(19) United States
(12) Patent Application Publication
(10) Pub. No.: US 2025/0328204 A1
(43) Pub. Date: Oct. 23, 2025

(54) ELECTRONIC DEVICE

(71) Applicant: Samsung Display Co., Ltd., Yongin-si (KR)

(72) Inventor: SANGHYUN LIM, Yongin-si (KR)

(21) Appl. No.: 19/017,325

(22) Filed: Jan. 10, 2025

(30) Foreign Application Priority Data
Apr. 19, 2024 (KR) 10-2024-0052427

(51) Int. Cl. G06F 3/041; G06F 3/044

(52) U.S. Cl. CPC G06F 3/04162; G06F 3/0442; G06F 2203/04111; G06F 2203/04112

(57) ABSTRACT

Disclosed is an electronic device which includes a sensor layer, and a sensor driver configured to drive the sensor layer, and configured to selectively operate in a first mode to sense a touch input or in a second mode to sense a pen input, wherein the sensor layer includes first electrodes arranged in a first direction, and including first sensing patterns spaced apart in a second direction crossing the first direction, and a first bridge pattern between the first sensing patterns, second electrodes arranged in the second direction, and including second sensing patterns spaced apart in the first direction, and a second bridge pattern between the second sensing patterns, and pen-sensing electrodes at a same layer as, and extending in an extension direction of, one of the first bridge pattern or the second bridge pattern.

### CROSS-REFERENCE TO RELATED APPLICATION

The present application claims priority to, and the benefit of, Korean Patent Application No. 10-2024-0052427, filed on Apr. 19, 2024, in the Korean Intellectual Property Office, the entire disclosure of which is incorporated herein by reference.

### BACKGROUND

Embodiments of the present disclosure described herein relate to an electronic device for sensing an input by a pen.

Multimedia electronic devices, such as a television, a mobile phone, a tablet computer, a notebook computer, a car navigation unit, a game machine, and the like, include a display device for displaying an image. The electronic devices may include a sensor layer (or, an input sensor) capable of providing a touch-based input method that enables a user to intuitively and conveniently input information or instructions in an easy and simple manner, in addition to a conventional input method such as a button, a keyboard, a mouse, or the like. The sensor layer may sense the user's touch or pressure. Meanwhile, pens for users accustomed to inputting information using writing instruments or pens for accurate touch inputs in specific application programs (e.g., application programs for sketching or drawing) are increasingly desired.

### SUMMARY

Embodiments of the present disclosure provide an electronic device for sensing an input by a pen.

According to one or more embodiments, an electronic device includes a sensor layer, and a sensor driver configured to drive the sensor layer, and configured to selectively operate in a first mode to sense a touch input or in a second mode to sense a pen input, wherein the sensor layer includes first electrodes arranged in a first direction, and including first sensing patterns spaced apart in a second direction crossing the first direction, and a first bridge pattern between the first sensing patterns, second electrodes arranged in the second direction, and including second sensing patterns spaced apart in the first direction, and a second bridge pattern between the second sensing patterns, and pen-sensing electrodes at a same layer as, and extending in an extension direction of, one of the first bridge pattern or the second bridge pattern.

The pen-sensing electrodes may be at a same layer as the second bridge pattern, wherein the pen-sensing electrodes and the second bridge pattern extend in the first direction.

The pen-sensing electrodes may have a bar shape extending in the first direction.

An outer edge of the pen-sensing electrodes may face an outer edge of the second bridge pattern adjacent thereto.

The pen-sensing electrodes may alternate with the second bridge patterns in the second direction.

A portion of one of the pen-sensing electrodes may overlap a portion of two of the second electrodes.

A portion of two of the pen-sensing electrodes may be in a sensing unit where one of the first electrodes and one of the second electrodes cross.

The first electrodes and the second sensing patterns may be at a different layer from the second bridge pattern, wherein the first sensing patterns and the first bridge pattern are integral in one of the first electrodes, and wherein the second sensing patterns and the second bridge pattern are connected through contact holes in one of the second electrodes.

The pen-sensing electrodes may be at a same layer as the second bridge pattern, wherein the pen-sensing electrodes and the second bridge pattern extend in the second direction.

The second sensing patterns may include a first protrusion on one side in the first direction, and a second protrusion on an opposite side in the first direction, the first and second protrusions extending in the first direction, wherein the second bridge pattern is connected to the second protrusion of one of the second sensing patterns and to the first protrusion of another of the second sensing patterns.

The first bridge pattern may include a first line portion configured to extend from one side of one of the first sensing patterns toward another one of the first sensing patterns adjacent thereto, a second line portion configured to extend from one side of the other of the first sensing patterns toward the one of the first sensing patterns, and a third line portion connecting the first and second line portions and extending in the first direction, wherein the second protrusion of the one of the second sensing patterns is between the other of the first sensing patterns and the third line portion, and wherein the first protrusion of the other of the second sensing patterns is between the one of the first sensing patterns and the third line portion.

The pen-sensing electrodes may be at a same layer as the first bridge pattern, wherein the pen-sensing electrodes and the first bridge pattern extend in the second direction.

The pen-sensing electrodes may have a bar shape extending in the first direction, wherein an outer edge of the pen-sensing electrodes faces an outer edge of the second bridge pattern adjacent thereto.

The pen-sensing electrodes may define a hole surrounding the first bridge pattern in plan view, wherein the pen-sensing electrodes overlap the first electrodes in a one-to-one correspondence.

The first sensing patterns and the second electrodes may be at a different layer from the first bridge pattern, wherein the first sensing patterns and the first bridge pattern in one of the first electrodes are connected through contact holes, and wherein the second sensing patterns and the second bridge pattern are integral in one of the second electrodes.

The electronic device may further include floated dummy patterns between adjacent ones of the pen-sensing electrodes.

The pen-sensing electrodes may define depressions recessed in a direction perpendicular to an extension direction of the second bridge pattern, wherein at least portions of the second bridge pattern are in the depressions of the pen-sensing electrodes adjacent to the second bridge pattern.

The pen-sensing electrodes may include first pen-sensing electrodes arranged in the first direction, and extending in the second direction, and second pen-sensing electrodes arranged in the second direction, and extending in the first direction.

The first pen-sensing electrodes may include third sensing patterns spaced apart in the second direction, and a third bridge pattern between the third sensing patterns, wherein the second pen-sensing electrodes include fourth sensing patterns spaced apart in the first direction, and a fourth bridge pattern between the fourth sensing patterns, wherein the second bridge pattern, the third sensing patterns, and the second pen-sensing electrodes are at a same layer, wherein the first electrodes, the second sensing patterns, and the third bridge pattern are at a same layer, and wherein the second pen-sensing electrodes and the second bridge pattern extend in the first direction.

The second bridge pattern and the fourth bridge pattern may be adjacent, are spaced apart in the second direction, and extend in parallel.

The second pen-sensing electrodes may define a hole surrounding the second bridge pattern in plan view.

The first pen-sensing electrodes and the second pen-sensing electrodes may be at different respective layers, wherein the second pen-sensing electrodes are at a same layer as the second bridge pattern, wherein the second pen-sensing electrodes and the second bridge pattern extend in the second direction, wherein the first pen-sensing electrodes extend in the first direction, and wherein the second pen-sensing electrodes have a bar shape extending in the second direction.

The sensor layer may include a lower conductive layer, a first conductive layer above the lower conductive layer, and a second conductive layer above the first conductive layer, wherein the first pen-sensing electrodes are in the lower conductive layer, wherein the second pen-sensing electrodes and the second bridge pattern are in the first conductive layer, wherein the first electrodes and the second sensing patterns are in the second conductive layer, and wherein the first pen-sensing electrodes have a bar shape extending in the first direction.

The sensor layer may include a lower conductive layer, a first conductive layer above the lower conductive layer, and a second conductive layer above the first conductive layer, wherein the second pen-sensing electrodes and the first bridge pattern are in the lower conductive layer, wherein the first pen-sensing electrodes are in the first conductive layer, wherein the first electrodes and the second sensing patterns are in the second conductive layer, and wherein the first pen-sensing electrodes define a hole surrounding, in plan view, a contact hole through which one of the second sensing patterns and the second bridge pattern are connected.

The first pen-sensing electrodes may include first divided electrodes spaced apart in the first direction, wherein the sensor layer further includes dummy patterns between the first divided electrodes, arranged in the first direction, and extending in the second direction.

The sensor layer may further include first type trace lines respectively connected to the second pen-sensing electrodes at a same layer as the first pen-sensing electrodes and extending to cross at least portions of the second pen-sensing electrodes in plan view while being insulated therefrom.

The second pen-sensing electrodes may include second divided electrodes arranged in the second direction, and including a first sub-electrode and a second sub-electrode spaced apart in the first direction, wherein the first type trace lines are connected to the first sub-electrode or the second sub-electrode of a corresponding one of the second pen-sensing electrode.

The second pen-sensing electrodes may include second divided electrodes arranged in the second direction, wherein the sensor layer further includes second type trace lines to connect first ends or second ends of the second divided electrodes in one second pen-sensing electrode, and wherein the second type trace lines include a first layer line at a same layer as the first pen-sensing electrodes, and a second layer line at a same layer as the second pen-sensing electrodes.

The first electrodes, the second electrodes, and the pen-sensing electrodes may have a mesh structure defining openings.

In the first mode, the first electrodes and the second electrodes may be configured to sense capacitance, and the pen-sensing electrodes may be grounded, wherein the second mode includes a pen-sensing driving mode in which the sensor driver is configured to receive reception signals based on induced currents flowing through the first electrodes, the second electrodes, and the pen-sensing electrodes.

The second mode may further include a charging driving mode in which a current path defined by at least the pen-sensing electrodes is formed, and the first electrodes and the second electrodes are floated.

According to one or more embodiments, an electronic device includes a sensor layer, and a sensor driver configured to drive the sensor layer, wherein the sensor layer includes first electrodes arranged in a first direction, and including first sensing patterns spaced apart in a second direction crossing the first direction, and a first bridge pattern between the first sensing patterns, second electrodes arranged in the second direction, and including second sensing patterns spaced apart in the first direction, and a second bridge pattern between the second sensing patterns, and auxiliary electrodes at a same layer as, and extending in an extension direction of, one of the first bridge pattern or the second bridge pattern such that outer edges face each other.

The first sensing patterns and the second sensing patterns may be above the auxiliary electrodes.

The sensor driver may be configured to selectively operate in a first mode to sense a touch input, or in a second mode to sense a pen input, wherein, in the first mode, the first electrodes and the second electrodes are configured to sense capacitance, and the auxiliary electrodes are grounded, and wherein, in the second mode, the sensor driver is configured to receive reception signals based on induced currents flowing through the first electrodes, the second electrodes, and the auxiliary electrodes.

### BRIEF DESCRIPTION OF THE DRAWINGS

The above and other aspects of the present disclosure will become apparent by describing in detail embodiments thereof with reference to the accompanying drawings.

FIG. 1A is a perspective view of an electronic device according to one or more embodiments of the present disclosure.

FIG. 1B is a rear perspective view of the electronic device according to one or more embodiments of the present disclosure.

FIG. 2 is a perspective view of an electronic device according to one or more embodiments of the present disclosure.

FIG. 3 is a perspective view of an electronic device according to one or more embodiments of the present disclosure.

FIG. 4 is a schematic sectional view of a display panel according to one or more embodiments of the present disclosure.

FIG. 5 is a view for explaining an operation of an electronic device according to one or more embodiments of the present disclosure.

FIG. 6A is a sectional view of the display panel according to one or more embodiments of the present disclosure;

FIG. 6B is a sectional view of a sensor layer according to one or more embodiments of the present disclosure.

FIG. 7 is a plan view of the sensor layer according to one or more embodiments of the present disclosure.

FIG. 8A is an enlarged plan view illustrating a portion of a sensing area according to one or more embodiments of the present disclosure.

FIG. 8B is a plan view illustrating a first conductive layer of a portion of the sensing area according to one or more embodiments of the present disclosure.

FIG. 8C is a plan view illustrating a second conductive layer of a portion of the sensing area according to one or more embodiments of the present disclosure.

FIG. 8D is a sectional view of the sensor layer taken along the line I-I′ illustrated in FIG. 8A according to one or more embodiments of the present disclosure.

FIG. 9A is an enlarged plan view of area AA′ illustrated in FIG. 8C.

FIG. 9B is an enlarged plan view of area BB′ illustrated in FIG. 8B.

FIG. 10A is an enlarged plan view illustrating a portion of a sensing area according to one or more embodiments of the present disclosure.

FIG. 10B is a plan view illustrating a first conductive layer of a portion of the sensing area according to one or more embodiments of the present disclosure.

FIG. 10C is a plan view illustrating a second conductive layer of a portion of the sensing area according to one or more embodiments of the present disclosure.

FIG. 11A is an enlarged plan view illustrating a portion of a sensing area according to one or more embodiments of the present disclosure.

FIG. 11B is a plan view illustrating a first conductive layer of a portion of the sensing area according to one or more embodiments of the present disclosure.

FIG. 12A is an enlarged plan view illustrating a portion of a sensing area according to one or more embodiments of the present disclosure.

FIG. 12B is a plan view illustrating a second conductive layer of a portion of the sensing area according to one or more embodiments of the present disclosure.

FIG. 13A is a plan view illustrating a first conductive layer of a portion of a sensing area according to one or more embodiments of the present disclosure.

FIG. 13B is an enlarged plan view of area CC′ illustrated in FIG. 13A.

FIG. 14 is a plan view illustrating a first conductive layer of a portion of a sensing area according to one or more embodiments of the present disclosure.

FIG. 15A is a schematic view illustrating one channel according to one or more embodiments of the present disclosure.

FIG. 15B is an equivalent circuit diagram illustrating a relationship between the one channel and a pen according to one or more embodiments of the present disclosure.

FIG. 16A is a graph depicting the magnitudes of currents depending on the position of the pen relative to the one channel.

FIG. 16B is a graph depicting the magnitude of a signal depending on the position of the pen relative to the one channel.

FIG. 17 is a plan view of a sensor layer according to one or more embodiments of the present disclosure.

FIG. 18A is a plan view illustrating a first conductive layer of a portion of a sensing area according to one or more embodiments of the present disclosure.

FIG. 18B is a plan view illustrating a second conductive layer of a portion of the sensing area according to one or more embodiments of the present disclosure.

FIG. 18C is a sectional view of the sensor layer taken along the line II-II′ illustrated in FIGS. 18A and 18B according to one or more embodiments of the present disclosure.

FIG. 18D is a sectional view of the sensor layer taken along the line III-III′ illustrated in FIGS. 18A and 18B according to one or more embodiments of the present disclosure.

FIG. 19 is a plan view illustrating a first conductive layer of a portion of the sensing area according to one or more embodiments of the present disclosure.

FIG. 20A is an enlarged plan view illustrating a portion of a sensing area according to one or more embodiments of the present disclosure.

FIG. 20B is a plan view illustrating a lower conductive layer of a portion of the sensing area according to one or more embodiments of the present disclosure.

FIG. 20C is a plan view illustrating a first conductive layer of a portion of the sensing area according to one or more embodiments of the present disclosure.

FIG. 20D is a sectional view of a sensor layer taken along the line IV-IV′ illustrated in FIG. 20A according to one or more embodiments of the present disclosure.

FIG. 21A is an enlarged plan view illustrating a portion of a sensing area according to one or more embodiments of the present disclosure.

FIG. 21B is a plan view illustrating a lower conductive layer of a portion of the sensing area according to one or more embodiments of the present disclosure.

FIG. 21C is a plan view illustrating a first conductive layer of a portion of the sensing area according to one or more embodiments of the present disclosure.

FIG. 22A is a plan view illustrating a second conductive layer according to one or more embodiments of the present disclosure.

FIG. 22B is a plan view illustrating a first conductive layer according to one or more embodiments of the present disclosure.

FIG. 22C is a plan view illustrating a lower conductive layer according to one or more embodiments of the present disclosure.

FIG. 23 is a view illustrating an operation of a sensor driver according to one or more embodiments of the present disclosure.

FIG. 24 is a view illustrating an operation of the sensor driver according to one or more embodiments of the present disclosure.

FIG. 25 is a view for explaining a first mode according to one or more embodiments of the present disclosure.

FIG. 26 is a view for explaining a second mode according to one or more embodiments of the present disclosure.

FIG. 27A is a graph depicting the waveform of a first signal according to one or more embodiments of the present disclosure.

FIG. 27B is a graph depicting the waveform of a second signal according to one or more embodiments of the present disclosure.

FIG. 28A is a view for explaining the second mode according to one or more embodiments of the present disclosure.

FIG. 28B is a view for explaining the second mode based on one sensing unit according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

The electronic or electric devices and/or any other relevant devices or components according to embodiments of the present disclosure described herein may be implemented utilizing any suitable hardware, firmware (e.g., an application-specific integrated circuit), software, or a combination of software, firmware, and hardware, to process data or digital signals. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Circuit hardware may include, for example, application specific integrated circuits (ASICs), general purpose or special purpose central processing units (CPUs) that is configured to execute instructions stored in a non-transitory storage medium, digital signal processors (DSPs), graphics processing units (GPUs), and programmable logic devices, such as field programmable gate arrays (FPGAs).

Software components may indicate data used by executable codes and/or executable codes in a storage medium which is able to be addressed. Accordingly, software components may be, for example, object-oriented software components, class components, and task components, and may include processes, functions, properties, procedures, subroutines, program code segments, drivers, firmware, microcodes, circuits, data, database, data structures, tables, arrangements or variables. Further, the various components of these devices may be a process or thread, running on one or more processors, in one or more computing devices, executing computer program instructions and interacting with other system components for performing the various functionalities described herein. The computer program instructions are stored in a memory that may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

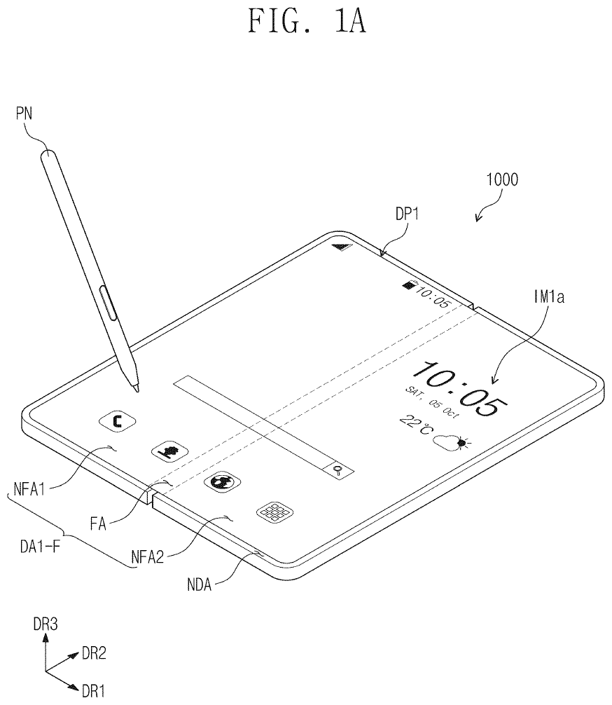

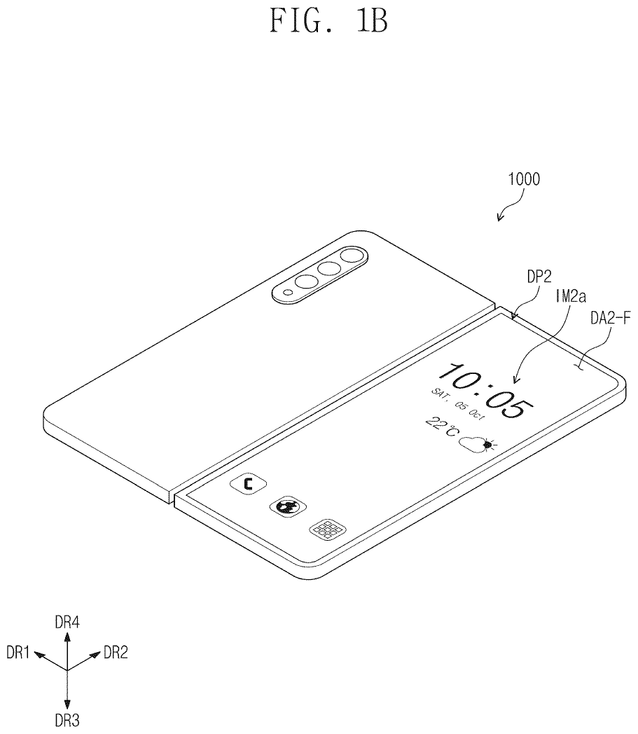

FIG. 1A is a perspective view of an electronic device 1000 according to one or more embodiments of the present disclosure. FIG. 1B is a rear perspective view of the electronic device 1000 according to one or more embodiments of the present disclosure.

Referring to FIGS. 1A and 1B, the electronic device 1000 may be a device activated depending on an electrical signal. For example, the electronic device 1000 may display an image and may sense an input applied from the outside. The external input may be a user input. The user input may include various types of external inputs, such as a part of a user's body, a pen PN, light, heat, or pressure.

The electronic device 1000 may include a first display panel DP1 and a second display panel DP2. The first display panel DP1 and the second display panel DP2 may be separate panels separated from each other. The first display panel DP1 may be referred to as a main display panel, and the second display panel DP2 may be referred to as an auxiliary display panel or an external display panel.

The first display panel DP1 may include a first display part DA1-F, and the second display panel DP2 may include a second display part DA2-F. The second display panel DP2 may have a smaller area than the first display panel DP1. The first display part DA1-F and the second display part DA2-F may have areas corresponding to the sizes of the first display panel DP1 and the second display panel DP2, respectively, and the first display part DA1-F may have a larger area than the second display part DA2-F.

In an unfolded state of the electronic device 1000, the first display part DA1-F may have a plane substantially parallel to a first direction DR1 and a second direction DR2. The thickness direction of the electronic device 1000 may be parallel to a third direction DR3 that crosses the first direction DR1 and the second direction DR2. Accordingly, front surfaces (or, upper surfaces) and rear surfaces (or, lower surfaces) of members constituting the electronic device 1000 may be defined based on the third direction DR3.

The first display panel DP1 or the first display part DA1-F may include a folding area FA that is folded and unfolded, and a plurality of non-folding areas NFA1 and NFA2 spaced apart from each other with the folding area FA therebetween. The second display panel DP2 may overlap one of the plurality of non-folding areas NFA1 or NFA2. For example, the second display panel DP2 may overlap the first non-folding area NFA1.

The display direction of a first image IM1a displayed on a portion of the first display panel DP1, for example, the first non-folding area NFA1 may be opposite to the display direction of a second image IM2a displayed on the second display panel DP2. For example, the first image IM1a may be displayed in the third direction DR3, and the second image IM2a may be displayed in a fourth direction DR4 opposite to the third direction DR3.

In one or more embodiments of the present disclosure, the folding area FA may be bent about a folding axis extending in a direction parallel to the long sides of the electronic device 1000, for example, in a direction parallel to the second direction DR2. The folding area FA has a certain curvature and a certain radius of curvature in a folded state of the electronic device 1000. The electronic device 1000 may be folded in an in-folding manner such that the first non-folding area NFA1 and the second non-folding area NFA2 face each other, and the first display part DA1-F is not exposed to the outside.

In one or more embodiments of the present disclosure, the electronic device 1000 may be folded in an out-folding manner such that the first display part DA1-F is exposed to the outside. In one or more embodiments of the present disclosure, the electronic device 1000 may be folded in an in-folding or out-folding manner in the unfolded state. However, the present disclosure is not limited thereto.

Although FIG. 1A illustrates an example that one folding area FA is defined (or, provided or included) in the electronic device 1000, the present disclosure is not limited thereto. For example, a plurality of folding axes and a plurality of folding areas corresponding thereto may be defined in the electronic device 1000, and the electronic device 1000 may be folded about the plurality of folding axes in an in-folding or out-folding manner in the unfolded state.

According to one or more embodiments of the present disclosure, at least one of the first display panel DP1 or the second display panel DP2 may sense an input by the pen PN without a digitizer. Because the digitizer for sensing the pen PN is omitted, an increase in the thickness and weight of the electronic device 1000 and a decrease in the flexibility of the electronic device 1000 otherwise caused by the addition of the digitizer may not occur. Accordingly, not only the first display panel DP1 but also the second display panel DP2 may be designed to sense the pen PN.

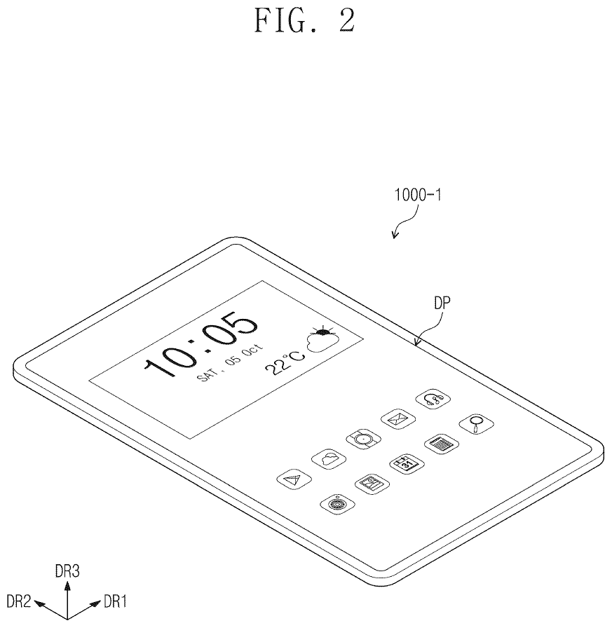

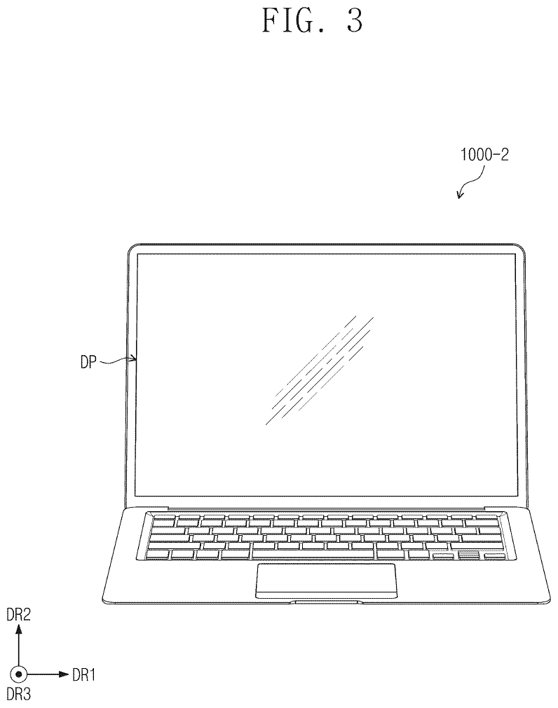

FIG. 2 is a perspective view of an electronic device 1000-1 according to one or more embodiments of the present disclosure. FIG. 3 is a perspective view of an electronic device 1000-2 according to one or more embodiments of the present disclosure.

FIG. 2 illustrates an example that the electronic device 1000-1 is a mobile phone, and the electronic device 1000-1 may include a display panel DP. FIG. 3 illustrates an example that the electronic device 1000-2 is a notebook computer, and the electronic device 1000-2 may include the display panel DP.

In one or more embodiments of the present disclosure, the display panel DP may sense an input applied from the outside. The external input may be a user input. The user input may include various types of external inputs, such as a part of the user's body, the pen PN (refer to FIG. 1A), light, heat, or pressure.

According to one or more embodiments of the present disclosure, the display panel DP may sense an input by the pen PN without a digitizer. Because the digitizer for sensing the pen PN is omitted, an increase in the thickness and weight of the electronic device 1000-1 or 1000-2 depending on the addition of the digitizer may not occur.

Although the foldable electronic device 1000 is illustrated in FIG. 1A and the bar-type electronic device 1000-1 is illustrated in FIG. 2, the present disclosure to be described below is not limited thereto. For example, the following descriptions may be applied to various electronic devices, such as a rollable electronic device, a slidable electronic device, and a stretchable electronic device.

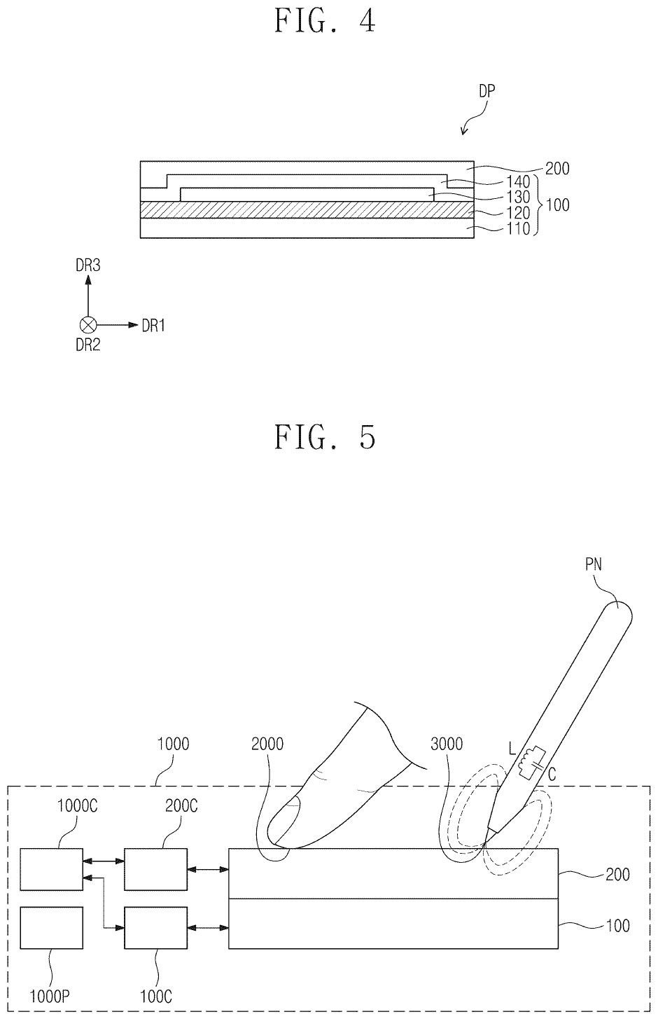

FIG. 4 is a schematic sectional view of the display panel DP according to one or more embodiments of the present disclosure.

Referring to FIG. 4, the display panel DP may include a display layer 100 and a sensor layer 200.

The display layer 100 may be a component that substantially generates an image. The display layer 100 may be an emissive display layer. For example, the display layer 100 may be an organic light-emitting display layer, an inorganic light-emitting display layer, an organic-inorganic light-emitting display layer, a quantum-dot display layer, a micro-LED display layer, or a nano-LED display layer. The display layer 100 may include a base layer 110, a circuit layer 120, a light-emitting element layer 130, and an encapsulation layer 140.

The base layer 110 may be a member that provides a base surface on which the circuit layer 120 is located. The base layer 110 may have a multi-layer structure or a single-layer structure. The base layer 110 may be a glass substrate, a metal substrate, a silicon substrate, or a polymer substrate, but is not particularly limited thereto.

The circuit layer 120 may be located on the base layer 110. The circuit layer 120 may include an insulating layer, a semiconductor pattern, a conductive pattern, and a signal line. An insulating layer, a semiconductor layer, and a conductive layer may be formed on the base layer 110 by a process, such as coating or deposition. The insulating layer, the semiconductor layer, and the conductive layer may be selectively subjected to patterning by performing a photolithography process a plurality of times.

The light-emitting element layer 130 may be located on the circuit layer 120. The light-emitting element layer 130 may include light-emitting elements. For example, the light-emitting element layer 130 may include an organic luminescent material, an inorganic luminescent material, an organic-inorganic luminescent material, a quantum dot, a quantum rod, a micro LED, or a nano LED.

The encapsulation layer 140 may be located on the light-emitting element layer 130. The encapsulation layer 140 may protect the light-emitting element layer 130 from foreign matter, such as moisture, oxygen, and dust particles.

The sensor layer 200 may be located on the display layer 100. The sensor layer 200 may sense an external input applied from the outside. The sensor layer 200 may be an integrated sensor continuously formed in the process of manufacturing the display layer 100. Alternatively, the sensor layer 200 may be an external sensor attached to the display layer 100. The sensor layer 200 may be referred to as a sensor, an input sensing layer, an input sensing panel, or an electronic device for sensing input coordinates.

According to one or more embodiments of the present disclosure, the sensor layer 200 may sense both an input by a passive input means, such as a part of the user's body and an input by an input device that generates a magnetic field having a certain resonant frequency. The input device may be referred to as a pen, an input pen, a magnetic pen, a stylus pen, or an electromagnetic resonance pen.

FIG. 5 is a view for explaining an operation of the electronic device 1000 according to one or more embodiments of the present disclosure.

Referring to FIG. 5, the electronic device 1000 may include the display layer 100, the sensor layer 200, a display driver 100C, a sensor driver 200C, a main driver 1000C, and a power circuit 1000P.

The sensor layer 200 may sense an externally applied first input 2000 or second input 3000. Each of the first input 2000 and the second input 3000 may be by means capable of providing a change in the capacitance of the sensor layer 200, or by means capable of causing an induced current in the sensor layer 200. For example, the first input 2000 may be a passive input, such as a part of the user's body. The second input 3000 may be the pen PN or an an RFIC tag. For example, the pen PN may be a passive type or an active type.

In one or more embodiments of the present disclosure, the pen PN may be a device that generates a magnetic field having a certain resonant frequency. The pen PN may transmit an output signal based on an electromagnetic resonance scheme. The pen PN may be referred to as an input device, an input pen, a magnetic pen, a stylus pen, or an electromagnetic resonance pen.

The pen PN may include an RLC resonance circuit, and the RLC resonance circuit may include an inductor L and a capacitor C. In one or more embodiments of the present disclosure, the RLC resonance circuit may be a variable resonance circuit that varies the resonant frequency. In this case, the inductor L may be a variable inductor, and/or the capacitor C may be a variable capacitor. However, the present disclosure is not particularly limited thereto.

The inductor L generates a current by a magnetic field formed in the electronic device 1000, for example, the sensor layer 200. However, the present disclosure is not particularly limited thereto. For example, when the pen PN operates in an active type, the pen PN may generate a current even though a magnetic field is not provided to the pen PN from the outside. The generated current is transferred to the capacitor C. The capacitor C charges the current input from the inductor L and discharges the charged current to the inductor L. Thereafter, the inductor L may emit a magnetic field having a resonant frequency. An induced current may flow in the sensor layer 200 by the magnetic field emitted from the pen PN. The induced current may be transferred to the sensor driver 200C as a reception signal (or, a sensing signal or other signal).

The main driver 1000C may control overall operation of the electronic device 1000. For example, the main driver 1000C may control operations of the display driver 100C and the sensor driver 200C. The main driver 1000C may include at least one microprocessor, and may further include a graphic controller. The main driver 1000C may be referred to as an application processor, a central processing unit, or a main processor.

The display driver 100C may drive the display layer 100. The display driver 100C may receive image data and a control signal from the main driver 1000C. The control signal may include various signals. For example, the control signal may include an input vertical synchronization signal, an input horizontal synchronization signal, a main clock, and a data enable signal.

The sensor driver 200C may drive the sensor layer 200. The sensor driver 200C may receive a control signal from the main driver 1000C. The control signal may include a clock signal of the sensor driver 200C. In addition, the control signal may further include a mode determination signal for determining a driving mode of the sensor driver 200C and the sensor layer 200.

The sensor driver 200C may be implemented with an integrated circuit (IC), and may be electrically connected with the sensor layer 200. For example, the sensor driver 200C may be directly mounted on a certain area of the display panel. Alternatively, the sensor driver 200C may be mounted on a separate printed circuit board using a chip-on-film (COF) method, and may be electrically connected with the sensor layer 200.

The sensor driver 200C and the sensor layer 200 may selectively operate in a first mode or a second mode. For example, the first mode may be a mode for sensing a touch input, for example, the first input 2000. The second mode may be a mode for sensing an input by the pen PN, for example, the second input 3000. The first mode may be referred to as a touch-sensing mode, and the second mode may be referred to as a pen-sensing mode.

Switching between the first mode and the second mode may be performed in various ways. For example, the sensor driver 200C and the sensor layer 200 may be driven in the first mode and the second mode in a time-division manner, and may sense the first input 2000 and the second input 3000. Alternatively, the switching between the first mode and the second mode may be performed by the user's selection or the user's action (or, input), or by activating or deactivating a corresponding application, one of the first mode or the second mode may be activated or deactivated or the driving mode may be switched from one mode to the other mode. In another case, while the sensor driver 200C and the sensor layer 200 alternately operate in the first mode and the second mode, when the first input 2000 is sensed, the sensor driver 200C and the sensor layer 200 may remain in the first mode, and when the second input 3000 is sensed, the sensor driver 200C and the sensor layer 200 may remain in the second mode.

The sensor driver 200C may calculate coordinate information of an input based on a signal received from the sensor layer 200 and may provide a coordinate signal having the coordinate information to the main driver 1000C. The main driver 1000C executes an operation corresponding to the user input, based on the coordinate signal. For example, the main driver 1000C may operate the display driver 100C such that a new application image is displayed on the display layer 100.

The power circuit 1000P may include a power management integrated circuit (PMIC). The power circuit 1000P may generate a plurality of driving voltages for driving the display layer 100, the sensor layer 200, the display driver 100C, and the sensor driver 200C. For example, the plurality of driving voltages may include a gate high-voltage, a gate low-voltage, a first driving voltage (e.g., an ELVSS voltage), a second driving voltage (e.g., an ELVDD voltage), an initialization voltage, and the like, but are not particularly limited to the examples.

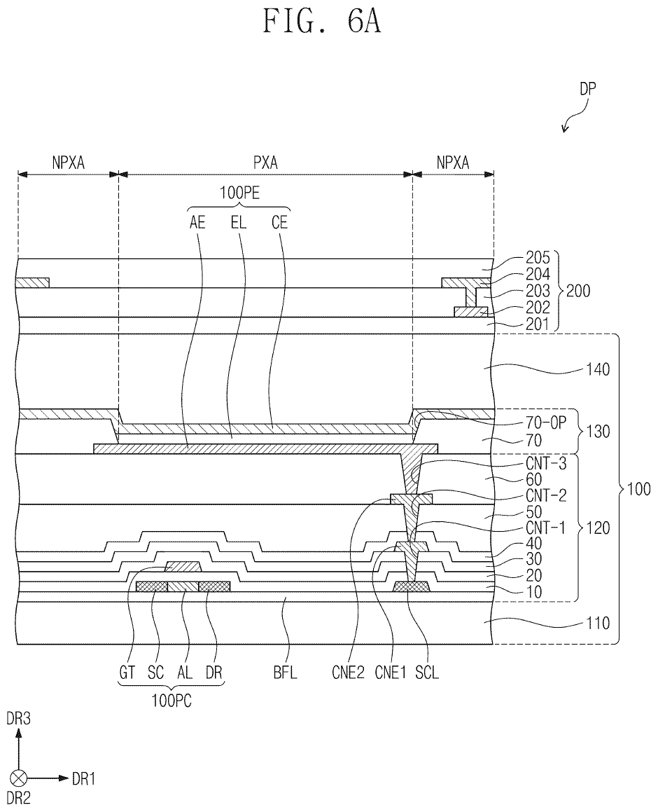

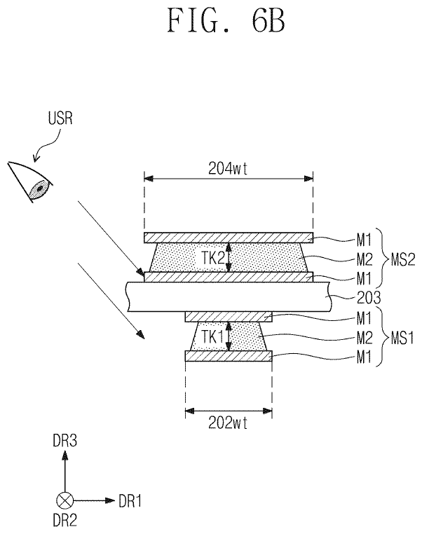

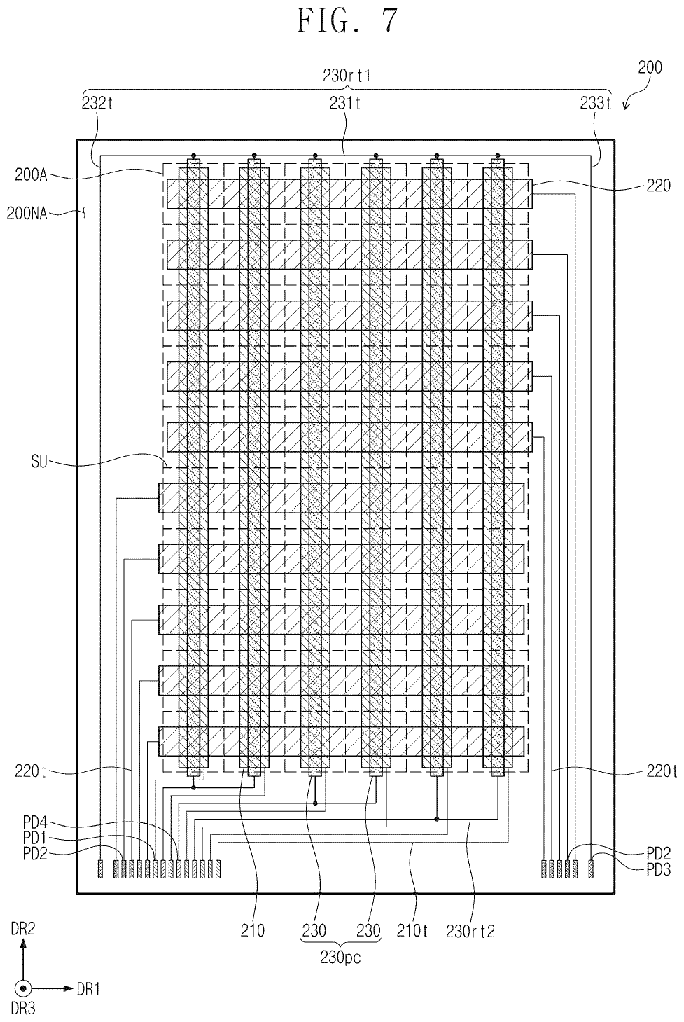

FIG. 6A is a sectional view of the display panel DP according to one or more embodiments of the present disclosure.

Referring to FIG. 6A, at least one buffer layer BFL is formed on the upper surface of the base layer 110 (as used herein, “formed on” or “located on” may mean “above”). The buffer layer BFL may improve the coupling force between the base layer 110 and a semiconductor pattern. The buffer layer BFL may be formed of multiple layers. Alternatively, the display layer 100 may further include a barrier layer. The buffer layer BFL may include at least one of silicon oxide, silicon nitride, or silicon oxy nitride. For example, the buffer layer BFL may include a structure in which silicon oxide layers and silicon nitride layers are alternately stacked one above another.

The semiconductor pattern SC, AL, DR, and SCL may be located on the buffer layer BFL. The semiconductor pattern SC, AL, DR, and SCL may include poly silicon. However, without being limited thereto, the semiconductor pattern SC, AL, DR, and SCL may include amorphous silicon, low-temperature polycrystalline silicon, or oxide semiconductor.

FIG. 6A illustrates only a portion of the semiconductor pattern SC, AL, DR, and SCL, and the semiconductor pattern may be additionally located in other areas. The semiconductor pattern SC, AL, DR, and SCL may be arranged according to a corresponding rule across pixels. The semiconductor pattern SC, AL, DR, and SCL may have different electrical properties depending on whether doping is performed or not. The semiconductor pattern SC, AL, DR, and SCL may include first areas SC, DR, and SCL having a high conductivity, and a second area AL having a low conductivity. The first areas SC, DR, and SCL may be doped with an N-type dopant or a P-type dopant. A P-type transistor may include a doped area that is doped with a P-type dopant, and an N-type transistor may include a doped area that is doped with an N-type dopant. The second area AL may be a non-doped area or may be an area more lightly doped than the first areas SC, DR, and SCL.

The first areas SC, DR, and SCL may have a higher conductivity than the second area AL, and may substantially serve as electrodes or signal lines. The second area AL may substantially correspond to an active area AL (or, a channel) of a transistor 100PC. In other words, one portion AL of the semiconductor pattern SC, AL, DR, and SCL may be the active area AL of the transistor 100PC, another portion SC or DR may be a source area SC or a drain area DR of the transistor 100PC, and the other portion SCL may be a connecting electrode or a connecting signal line SCL.

Each of the pixels may have an equivalent circuit including a plurality of transistors, one capacitor, and at least one light-emitting element, and the equivalent circuit of the pixel may be modified in various forms. In FIG. 6A, one transistor 100PC and one light-emitting element 100PE that are included in the pixel are illustrated.

The source area SC, the active area AL, and the drain area DR of the transistor 100PC may be formed from the semiconductor pattern SC, AL, DR, and SCL. The source area SC and the drain area DR may extend from the active area AL in opposite directions on the section. In FIG. 6A, a portion of the connecting signal line SCL formed from the semiconductor pattern SC, AL, DR, and SCL is illustrated. In one or more embodiments, the connecting signal line SCL may be connected to the drain area DR of the transistor 100PC when viewed from above the plane.

A first insulating layer 10 may be located on the buffer layer BFL. The first insulating layer 10 may commonly overlap the plurality of pixels, and may cover the semiconductor pattern SC, AL, DR, and SCL. The first insulating layer 10 may be an inorganic layer and/or an organic layer, and may have a single-layer structure or a multi-layer structure. The first insulating layer 10 may include at least one of aluminum oxide, titanium oxide, silicon oxide, silicon nitride, silicon oxy nitride, zirconium oxide, or hafnium oxide. The first insulating layer 10 may be a single silicon oxide layer. Not only the first insulating layer 10, but also insulating layers of the circuit layer 120 that will be described below may be inorganic layers and/or organic layers, and may have a single-layer structure or a multi-layer structure. The inorganic layers may include at least one of the aforementioned materials, but are not limited thereto.

A gate GT of the transistor 100PC is located on the first insulating layer 10. The gate GT may be a portion of a metal pattern. The gate GT overlaps the active area AL. The gate GT may function as a mask in the process of doping or reducing the semiconductor pattern SC, AL, DR, and SCL.

A second insulating layer 20 may be located on the first insulating layer 10, and may cover the gate GT. The second insulating layer 20 may commonly overlap the pixels. The second insulating layer 20 may be an inorganic layer and/or an organic layer, and may have a single-layer structure or a multi-layer structure. The second insulating layer 20 may include at least one of silicon oxide, silicon nitride, or silicon oxy nitride. The second insulating layer 20 may have a multi-layer structure including a silicon oxide layer and a silicon nitride layer.

A third insulating layer 30 may be located on the second insulating layer 20. The third insulating layer 30 may have a single-layer structure or a multi-layer structure. For example, the third insulating layer 30 may have a multi-layer structure including a silicon oxide layer and a silicon nitride layer.

A first connecting electrode CNE1 may be located on the third insulating layer 30. The first connecting electrode CNE1 may be connected to the connecting signal line SCL through a contact hole CNT-1 penetrating the first, second, and third insulating layers 10, 20, and 30.

A fourth insulating layer 40 may be located on the third insulating layer 30. The fourth insulating layer 40 may be a single silicon oxide layer. A fifth insulating layer 50 may be located on the fourth insulating layer 40. The fifth insulating layer 50 may be an organic layer.

A second connecting electrode CNE2 may be located on the fifth insulating layer 50. The second connecting electrode CNE2 may be connected to the first connecting electrode CNE1 through a contact hole CNT-2 penetrating the fourth insulating layer 40 and the fifth insulating layer 50.

A sixth insulating layer 60 may be located on the fifth insulating layer 50 and may cover the second connecting electrode CNE2. The sixth insulating layer 60 may be an organic layer.

The light-emitting element layer 130 may be located on the circuit layer 120. The light-emitting element layer 130 may include the light-emitting element 100PE. For example, the light-emitting element layer 130 may include an organic luminescent material, an inorganic luminescent material, an organic-inorganic luminescent material, a quantum dot, a quantum rod, a micro LED, or a nano LED. Hereinafter, the light-emitting element 100PE will be described as an organic light-emitting element. However, the present disclosure is not particularly limited thereto.

The light-emitting element 100PE may include a first electrode AE, an emissive layer EL, and a second electrode CE.

The first electrode AE may be located on the sixth insulating layer 60. The first electrode AE may be connected to the second connecting electrode CNE2 through a contact hole CNT-3 penetrating the sixth insulating layer 60.

A pixel defining layer 70 may be located on the sixth insulating layer 60 and may cover a portion of the first electrode AE. The pixel defining layer 70 has an opening 70-OP defined therein. The opening 70-OP of the pixel defining layer 70 exposes at least a portion of the first electrode AE.

The first display part DA1-F (refer to FIG. 1A) may include an emissive area PXA, and a non-emissive area NPXA adjacent to the emissive area PXA. The non-emissive area NPXA may surround the emissive area PXA (e.g., in plan view). The emissive area PXA is defined to correspond to a partial region of the first electrode AE exposed by the opening 70-OP.

The emissive layer EL may be located on the first electrode AE. The emissive layer EL may be located in an area corresponding to the opening 70-OP. Although FIG. 6A illustrates an example that the emissive layer EL is located in the opening 70-OP, the present disclosure is not particularly limited thereto. For example, the emissive layer EL may extend to cover the side surface of the pixel defining layer 70 that defines the opening 70-OP and a portion of the upper surface of the pixel defining layer 70.

In one or more embodiments of the present disclosure, the emissive layer EML may be separately formed for each of the pixels. When the emissive layer EL is separately formed for each of the pixels, the emissive layers EL may each emit at least one of blue light, red light, or green light. However, without being limited thereto, the emissive layer EL may be connected to the pixels and may be commonly included in the pixels. In this case, the emissive layer EL may provide blue light or white light.

The second electrode CE may be located on the emissive layer EL. The second electrode CE may have a one-body shape (e.g., may be integrally formed), and may be commonly included in the plurality of pixels.

In one or more embodiments of the present disclosure, a hole control layer may be located between the first electrode AE and the emissive layer EL. The hole control layer may be commonly located in the emissive area PXA and the non-emissive area NPXA. The hole control layer may include a hole transport layer, and may further include a hole injection layer. An electron control layer may be located between the emissive layer EL and the second electrode CE. The electron control layer may include an electron transport layer and may further include an electron injection layer. The hole control layer and the electron control layer may be commonly formed in the plurality of pixels using an open mask or an ink-jet process.

The encapsulation layer 140 may be located on the light-emitting element layer 130. The encapsulation layer 140 may include an inorganic layer, an organic layer, and an inorganic layer that are sequentially stacked one above another. However, layers constituting the encapsulation layer 140 are not limited thereto. The inorganic layers may protect the light-emitting element layer 130 from moisture and oxygen, and the organic layer may protect the light-emitting element layer 130 from foreign matter, such as dust particles. The inorganic layers may include a silicon nitride layer, a silicon oxy nitride layer, a silicon oxide layer, a titanium oxide layer, or an aluminum oxide layer. The organic layer may include an acrylic organic layer, but is not limited thereto.

The sensor layer 200 may include a base layer 201, a first conductive layer 202, an intermediate insulating layer 203, a second conductive layer 204, and a cover insulating layer 205.

The base layer 201 may be an inorganic layer including at least one of silicon nitride, silicon oxy nitride, or silicon oxide. Alternatively, the base layer 201 may be an organic layer including an epoxy resin, an acrylic resin, or an imide-based resin. The base layer 201 may have a single-layer structure or may have a multi-layer structure stacked in the third direction DR3. In one or more embodiments of the present disclosure, the sensor layer 200 may not include the base layer 201.

Each of the first conductive layer 202 and the second conductive layer 204 may have a single-layer structure or may have a multi-layer structure stacked in the third direction DR3.

Each of the first conductive layer 202 and the second conductive layer 204 that have a single-layer structure may include a metal layer or a transparent conductive layer. The metal layer may include molybdenum, silver, titanium, copper, aluminum, or an alloy thereof. The transparent conductive layer may include transparent conductive oxide, such as indium tin oxide (ITO), indium zinc oxide (IZO), zinc oxide (ZnO), indium zinc tin oxide (IZTO), or the like. In addition, the transparent conductive layer may include a conductive polymer, such as poly(3,4-ethylenedioxythiophene) (PEDOT), a metal nano wire, or graphene.

Each of the first conductive layer 202 and the second conductive layer 204 that have a multi-layer structure may include metal layers. The meal layers may have, for example, a three-layer structure of titanium/aluminum/titanium. The conductive layers having the multi-layer structure may include at least one metal layer and at least one transparent conductive layer.

In one or more embodiments of the present disclosure, the thickness of the first conductive layer 202 may be greater than or equal to the thickness of the second conductive layer 204. When the thickness of the first conductive layer 202 is greater than the thickness of the second conductive layer 204, the resistance of a component (e.g., the resistance of an electrode, a sensing pattern, or a bridge pattern) included in the first conductive layer 202 may be decreased. In addition, because the first conductive layer 202 is located under the second conductive layer 204, the probability that components included in the first conductive layer 202 will be visually recognized due to reflection of external light may be lower than that of the second conductive layer 204, even though the thickness of the first conductive layer 202 is increased.

At least one of the intermediate insulating layer 203 or the cover insulating layer 205 may include an inorganic film. The inorganic film may include at least one of aluminum oxide, titanium oxide, silicon oxide, silicon nitride, silicon oxy nitride, zirconium oxide, or hafnium oxide.

At least one of the intermediate insulating layer 203 or the cover insulating layer 205 may include an organic film. The organic film may include at least one of an acrylic resin, a methacrylic resin, a polyisoprene resin, a vinyl resin, an epoxy resin, a urethane-based resin, a celluosic resin, a siloxane-based resin, a polyimide resin, a polyamide resin, or a perylene-based resin.

Although it has been described that the sensor layer 200 includes the first conductive layer 202 and the second conductive layer 204, that is, a total of two conductive layers, the present disclosure is not particularly limited thereto. For example, the sensor layer 200 may include three or more conductive layers.

FIG. 6B is a sectional view of the sensor layer 200 according to one or more embodiments of the present disclosure.

Referring to FIGS. 6A and 6B, the second width 204 wt of a second mesh line MS2 included in the second conductive layer 204 may be greater than or equal to the first width 202 wt of a first mesh line MS1 included in the first conductive layer 202. When a user USR looks at the first mesh line MS1 and the second mesh line MS2 from the side, the probability that the first mesh line MS1 will be visually recognized by the user USR may be decreased because the first mesh line MS1 has a smaller width than the second mesh line MS2.

Each of the first mesh line MS1 and the second mesh line MS2 may include first metal layers M1 and a second metal layer M2 located between the first metal layers M1. For example, the first metal layers M1 may include titanium (Ti), and the second metal layer M2 may include aluminum (AI). However, this is illustrative, and the present disclosure is not particularly limited thereto.

In one or more embodiments of the present disclosure, the first thickness TK1 of the second metal layer M2 of the first mesh line MS1 and the second thickness TK2 of the second metal layer M2 of the second mesh line MS2 may be substantially the same as each other, but are not particularly limited thereto. For example, the first thickness TK1 may be greater than the second thickness TK2. Alternatively, the second thickness TK2 may be greater than the first thickness TK1. In one or more embodiments of the present disclosure, each of the first thickness TK1 and the second thickness TK2 may be 1000 angstroms or more, for example, 6000 angstroms.

FIG. 7 is a plan view of the sensor layer 200 according to one or more embodiments of the present disclosure.

Referring to FIG. 7, a sensing area 200A, and a peripheral area 200NA adjacent to the sensing area 200A, may be defined in the sensor layer 200.

The sensor layer 200 may include a plurality of first electrodes 210, a plurality of second electrodes 220, and a plurality of third electrodes 230 located in the sensing area 200A.

Each of the first electrodes 210 may cross the second electrodes 220. The first electrode 210 may extend in the second direction DR2. The first electrodes 210 may be arranged in the first direction DR1 so as to be spaced apart from one another. Each of the second electrodes 220 may extend in the first direction DR1. The second electrodes 220 may be arranged in the second direction DR2 so as to be spaced apart from one another. A sensing unit SU of the sensor layer 200 may be an area where one first electrode 210 and one second electrode 220 cross each other.

Although six first electrodes 210, ten second electrodes 220, and sixty sensing units SU are illustrated in FIG. 7, the number of first electrodes 210 and the number of second electrodes 220 are not limited thereto.

Each of the third electrodes 230 may extend in the second direction DR2. The third electrodes 230 may be arranged in the first direction DR1 so as to be spaced apart from one another. One third electrode 230 may at least partially overlap one first electrode 210. The third electrodes 230 may be referred to as pen-sensing electrodes or auxiliary electrodes. According to one or more embodiments of the present disclosure, the capacitance (or, coupling capacitance) between one first electrode 210 and one third electrode 230 may be adjusted by adjusting the overlapping area between the one first electrode 210 and the one third electrode 230. Alternatively, according to one or more embodiments of the present disclosure, one first electrode 210 may overlap a plurality of (e.g., two) third electrodes 230. In this case, the capacitance (or, coupling capacitance) between the one first electrode 210 and the plurality of third electrodes 230 may be adjusted by adjusting the overlapping area between the one first electrode 210 and the plurality of third electrodes 230.

Although FIG. 7 illustrates an example that the third electrodes 230 overlap the first electrodes 210 in a one-to-one correspondence, this is illustrative, and embodiments are not limited thereto. For example, one third electrode 230 may overlap a plurality of first electrodes 210.

In one or more embodiments, each of the third electrodes 230 may extend in the first direction DR1, and the third electrodes 230 may be arranged in the second direction DR2 so as to be spaced apart from one another. In this case, one third electrode 230 may at least partially overlap one second electrode 220 (or, a plurality of second electrodes 220). According to one or more embodiments of the present disclosure, the capacitance (or, coupling capacitance) between one second electrode 220 and one third electrode 230 (or, a plurality of third electrodes 230) may be adjusted by adjusting the overlapping area between the one second electrode 220 and the one third electrode 230 (or, the plurality of third electrodes 230).

In one or more embodiments of the present disclosure, at least some of the third electrodes 230 may be connected in parallel. FIG. 7 illustrates an example that two third electrodes 230 are connected in parallel to form a third electrode group 230pc, and three third electrode groups 230pc may be arranged in the first direction DR1. However, the number of third electrodes 230 constituting the third electrode group 230pc is not limited thereto. For example, one third electrode group 230pc may include only one third electrode 230, or may include three or more third electrodes 230.

As the number of third electrodes 230 included in the third electrode group 230pc and connected in parallel is increased, the resistance of the third electrode group 230pc may be lowered, and power efficiency and sensing sensitivity may be improved. In contrast, as the number of third electrodes 230 included in the third electrode group 230pc is decreased, a loop coil pattern formed using the third electrode group 230pc may be implemented in more various forms.

The sensor layer 200 may further include a plurality of first trace lines 210t located in the peripheral area 200NA, a plurality of first pads PD1 connected to the first trace lines 210t in a one-to-one correspondence, a plurality of second trace lines 220t, and a plurality of second pads PD2 connected to the second trace lines 220t in a one-to-one correspondence. The first trace lines 210t may be electrically connected to the first electrodes 210 in a one-to-one correspondence. The second trace lines 220t may be electrically connected to the second electrodes 220 in a one-to-one correspondence.

The sensor layer 200 may further include a third trace line 230rt1 located in the peripheral area 200NA, a plurality of third pads PD3 connected to one end and an opposite end of the third trace line 230rt1, fourth trace lines 230rt2, and fourth pads PD4 connected to the fourth trace lines 230rt2 in a one-to-one correspondence.

The third trace line 230rt1 may be electrically connected with the third electrodes 230. In one or more embodiments of the present disclosure, the third trace line 230rt1 may be electrically connected with all of the third electrodes 230. The third trace line 230rt1 may include a first line portion 231t that extends in the first direction DR1 and that is electrically connected to the third electrodes 230, a second line portion 232t extending from a first end of the first line portion 231t in the second direction DR2, and a third line portion 233t extending from a second end of the first line portion 231t in the second direction DR2.

In one or more embodiments of the present disclosure, each of the resistance of the second line portion 232t and the resistance of the third line portion 233t may be substantially the same as the resistance of one third electrode among the third electrodes 230. Accordingly, the second line portion 232t and the third line portion 233t may serve as the third electrodes 230, and the same effect as placing the third electrodes 230 in the peripheral area 200NA may be obtained. For example, one of the second line portion 232t or the third line portion 233t and one of the third electrodes 230 may form a coil. Accordingly, the pen located in an area adjacent to the peripheral area 200NA may also be sufficiently charged by a loop including the second line portion 232t or the third line portion 233t.

In one or more embodiments of the present disclosure, the widths of the second line portion 232t and the third line portion 233t in the first direction DR1 may be adjusted to adjust the resistance of the second line portion 232t and the resistance of the third line portion 233t. However, this is merely illustrative, and the first to third line portions 231t, 232t, and 233t may have substantially the same width.

The fourth trace lines 230rt2 may be connected to the third electrode groups 230pc in a one-to-one correspondence. That is, the number of fourth trace lines 230rt2 may correspond to the number of third electrode groups 230pc. In FIG. 7, three fourth trace lines 230rt2 and three third electrode groups 230pc are illustrated as an example.

In one or more embodiments of the present disclosure, the fourth trace lines 230rt2 and the fourth pads PD4 may be omitted, and a charging driving mode for charging the pen may be omitted. In this case, even though a magnetic field is not provided from the sensor layer 200, the sensor layer 200 may sense an input by an active pen capable of emitting a magnetic field.

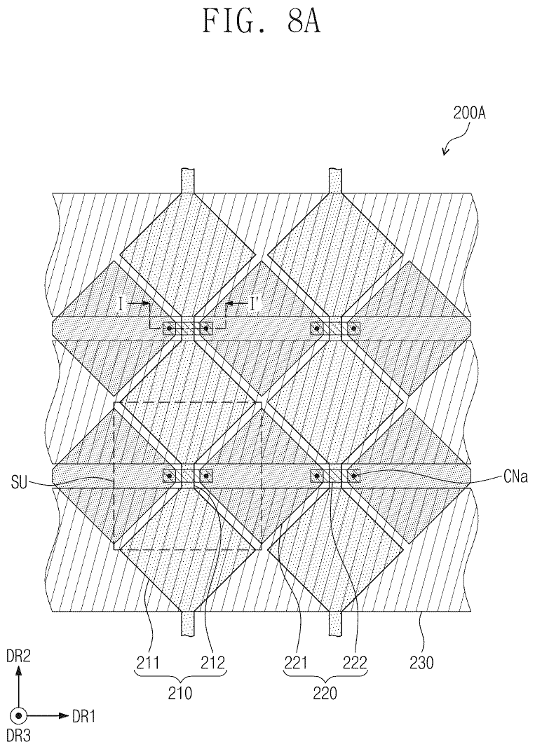

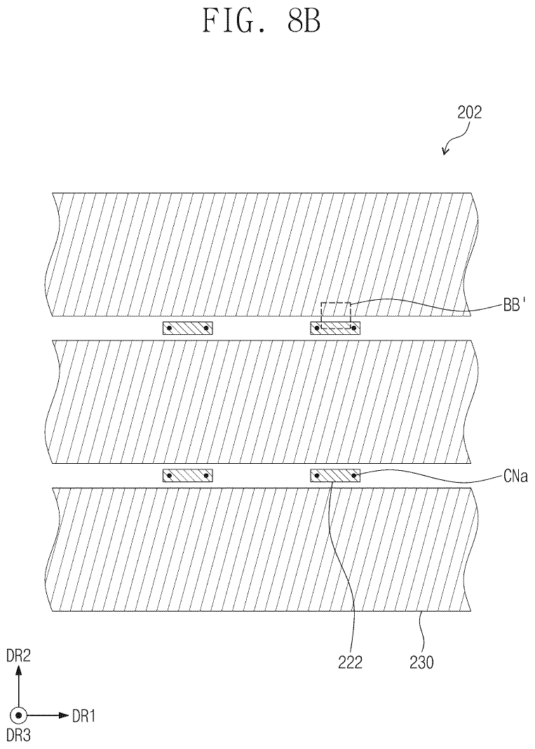

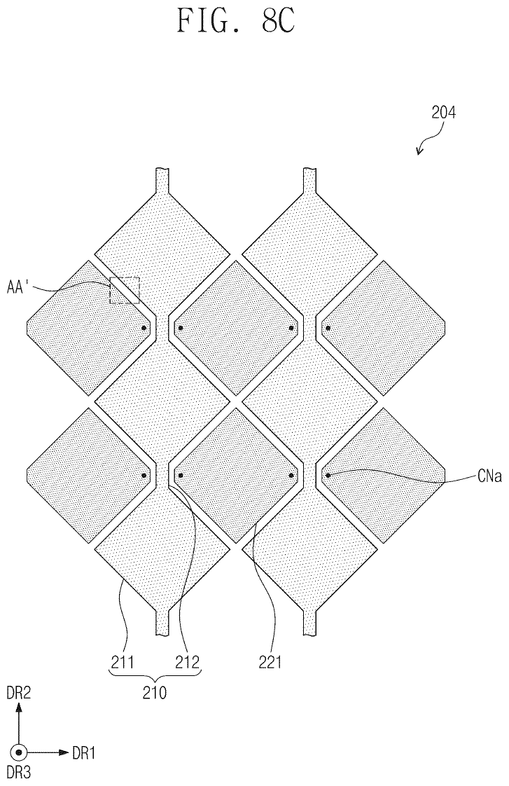

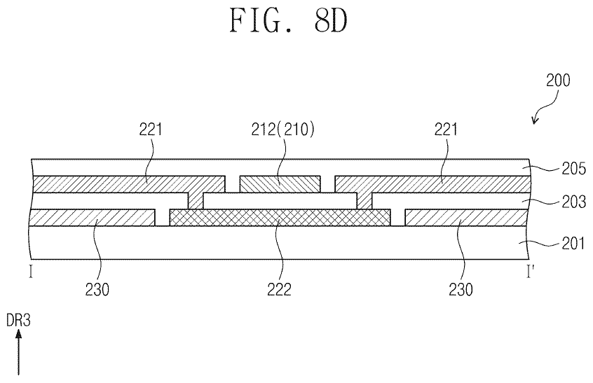

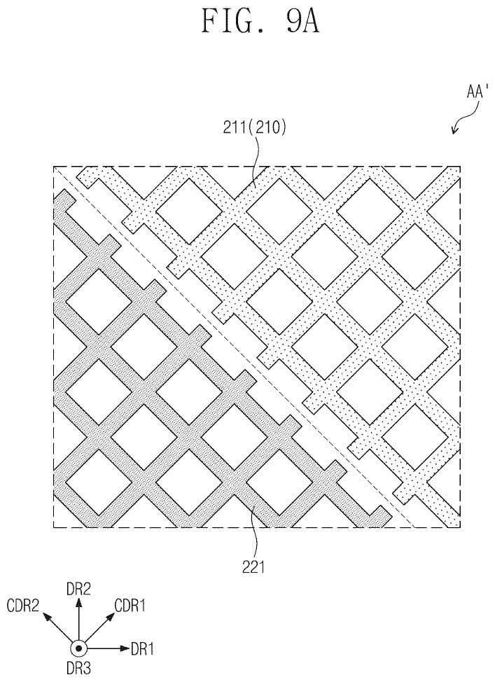

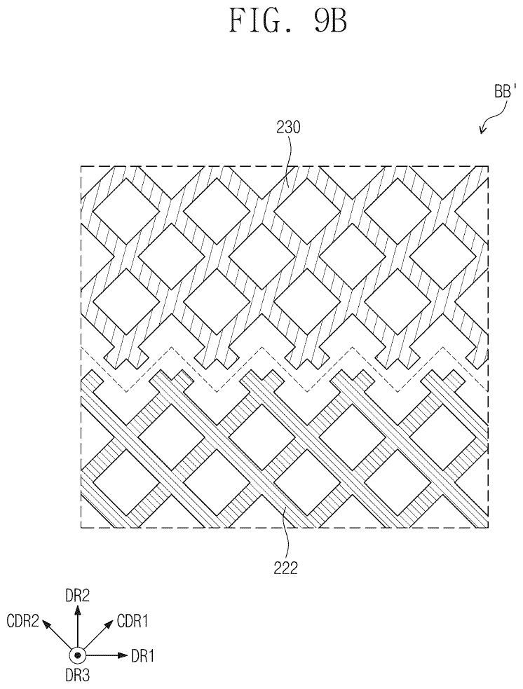

FIG. 8A is an enlarged plan view illustrating a portion of the sensing area 200A according to one or more embodiments of the present disclosure. FIG. 8B is a plan view illustrating the first conductive layer 202 of a portion of the sensing area 200A according to one or more embodiments of the present disclosure. FIG. 8C is a plan view illustrating the second conductive layer 204 of a portion of the sensing area 200A according to one or more embodiments of the present disclosure. FIG. 8D is a sectional view of the sensor layer 200 taken along the line I-I′ illustrated in FIG. 8A according to one or more embodiments of the present disclosure. FIG. 9A is an enlarged plan view of area AA′ illustrated in FIG. 8C. FIG. 9B is an enlarged plan view of area BB′ illustrated in FIG. 8B.

FIGS. 8A to 8C are enlarged views illustrating portions of two first electrodes 210 and two second electrodes 220 crossing each other and portions of three third electrodes 230 overlapping the two second electrodes 220.

Referring to FIGS. 8A to 8D, each of the first electrodes 210 may include first sensing patterns 211 and first bridge patterns 212. In one first electrode 210, the first sensing patterns 211 may be arranged in the second direction DR2, and each of the first bridge patterns 212 may be located between the first sensing patterns 211 to connect the adjacent first sensing patterns 211. The first bridge pattern 212 may extend in the second direction DR2. For one first electrode 210, the first sensing patterns 211 and the first bridge patterns 212 may form a one-body shape (e.g., may be integrally formed). In the case of the first sensing patterns 211 and the first bridge patterns 212 that form the one-body shape, the first sensing patterns 211 may be referred to as first sensing portions or first sensing parts, and the first bridge patterns 212 may be referred to as first bridge portions, first bridge parts, first connecting portions, or first connecting parts.

Each of the second electrodes 220 may include second sensing patterns 221 and second bridge patterns 222. In one second electrode 220, the second sensing patterns 221 may be arranged in the first direction DR1, and each of the second bridge patterns 222 may connect the adjacent second sensing patterns 221. The second sensing patterns 221 and the second bridge patterns 222 may be electrically connected with each other through contact holes CNa. Each of the second bridge patterns 222 may extend in the first direction DR1. For one second electrode 220, the second sensing patterns 221 and the second bridge patterns 222 may be located on different layers so as to be spaced apart from each other.

The first electrodes 210 may be located on the same layer as the second sensing patterns 221. For example, the second sensing patterns 221 adjacent to each other in the first direction DR1 may be spaced apart from each other with one first electrode 210 therebetween. The second bridge patterns 222 may be located on a layer that is different from the layer on which the first electrodes 210 are located. The second bridge patterns 222 may be insulated from the first electrodes 210, and may cross the first electrodes 210.

The third electrodes 230 may be located on the same layer as the second bridge patterns 222. Each of the third electrodes 230 may extend in the same direction as the extension direction of the second bridge pattern 222. The third electrode 230 may extend in the same direction as the arrangement direction of the second sensing patterns 221 or the extension direction of the second electrode 220. The third electrode 230 may extend in the first direction DR1. The extension direction of the third electrode 230 may be the same as the extension direction of the bridge pattern located on the same layer, the arrangement direction of the sensing patterns connected by the bridge pattern located on the same layer, or the extension direction of the electrode including the bridge pattern located on the same layer.

The third electrodes 230 may be spaced apart from the second bridge patterns 222. The third electrodes 230 may alternate with the second bridge patterns 222 of the second electrodes 220 in the second direction DR2. The second bridge patterns 222 included in one second electrode 220 may be located between the third electrodes 230 adjacent to each other in the second direction DR2. In other words, the second bridge patterns 222 arranged in the first direction DR1 may be located between the third electrodes 230 adjacent to each other in the second direction DR2. Outer edges of the second bridge pattern 222 and the third electrode 230 adjacent to each other may face each other. In other words, a portion of the outer edge of the second bridge pattern 222 and a portion of the outer edge of the third electrode adjacent to each other may face each other.

Each of the third electrodes 230 may have a bar shape extending in one direction. As the shape of an electrode is close to a bar shape, a resistance path may be shortened. Accordingly, the resistance of the third electrodes 230 may be decreased as the resistance path of the third electrodes 230 is shortened. As a result, the pen-sensing sensitivity of the sensor layer 200 may be improved.

Each of the third electrodes 230 may extend in the same direction as the extension direction of the bridge pattern located on the same layer. Accordingly, the third electrode 230 may be designed to have a wide width while having a bar shape. That is, a space in which the third electrode 230 in a bar shape is capable of having an increased or maximum width may be provided. When each of the third electrodes extends in the direction perpendicular to the extension direction of the bridge pattern located on the same layer unlike in one or more embodiments, the width of the third electrode may be relatively narrow due to the length of the bridge pattern in the extension direction.

One third electrode 230 may overlap each of the sensing patterns included in the first electrode 210 or the second electrode 220 that has the same extension direction. In one or more embodiments, one portion of one third electrode 230 may overlap a portion of each of second sensing patterns 221 included in one second electrode 220, and another portion of the one third electrode 230 may overlap a portion of each of second sensing patterns 221 included in another second electrode 220. That is, one third electrode 230 may overlap portions of two second electrodes 220. One portion of each of the second sensing patterns 221 included in one second electrode 220 may overlap a portion of one third electrode 230, and another portion of each of the second sensing patterns 221 included in the one second electrode 220 may overlap a portion of another third electrode 230. That is, one second electrode 220 may overlap portions of two third electrodes 230.

Two third electrodes 230 spaced apart from each other may be included in one sensing unit SU where one first electrode 210 and one second electrode 220 cross each other. One third electrode 230 may be commonly included in sensing units SU adjacent to each other in the direction perpendicular to the extension direction of the third electrode 230 (e.g., in the second direction DR2).

Referring to FIGS. 8A, 8B, and 8D, the second bridge patterns 222 of the second electrodes 220 and the third electrodes 230 may be located on the same layer, and may include the same material. For example, the second bridge patterns 222 and the third electrodes 230 may be included in the first conductive layer 202.

Referring to FIGS. 8A, 8C, and 8D, the first sensing patterns 211 and the first bridge patterns 212 of the first electrodes 210, and the second sensing patterns 221 of the second electrodes 220, may be located on the same layer, and may include the same material. For example, the first electrodes 210 and the second sensing patterns 221 may be included in the second conductive layer 204. The second sensing patterns 211 and the second bridge patterns 222 may be electrically connected with each other through the contact holes CNa defined in the intermediate insulating layer 203.

The first sensing patterns 211 and the second sensing patterns 221 may be located above the third electrodes 230. Because the first and second sensing patterns 211 and 221 that sense capacitance in the first mode are located in the upper conductive layer (that is, the second conductive layer 204), it may be easy to form capacitance with the first input 2000 (refer to FIG. 5), such as a touch input, and the sensing sensitivity of the first input may be further improved. The third electrodes 230 that cause or sense electromagnetic induction in the second mode may be located in the lower conductive layer (that is, the first conductive layer 202) different from the conductive layer in which the first and second sensing patterns 211 and 221 are located, and thus most of the lower conductive layer may be used to place the third electrodes 230. Accordingly, a design for reducing or minimizing the resistance of the third electrodes 230 may be performed, and the sensing sensitivity of the second input may be further improved.

Referring to FIGS. 8B, 8C, 9A, and 9B, the first electrodes 210, the second electrodes 220, and the third electrodes 230 may each have a mesh structure. The mesh structure may include a plurality of mesh lines. Each of the plurality of mesh lines may have a shape extending in a certain direction. The plurality of mesh lines may be connected with one another. The shape may have various shapes, such as a straight line, a line having protrusions, and an uneven line. Openings at least partially surrounded by the mesh lines may be defined (or, provided or formed) in the mesh structure. The openings may overlap the emissive area PXA (refer to FIG. 6A), and the mesh lines may overlap the non-emissive area NPXA (refer to FIG. 6A). However, the present disclosure is not particularly limited thereto.

FIGS. 9A and 9B illustrate an example that the mesh structure includes mesh lines extending in a first crossing direction CDR1 that crosses the first direction DR1 and the second direction DR2, and mesh lines extending in a second crossing direction CDR2 that crosses the first crossing direction CDR1. However, the extension directions of the mesh lines constituting the mesh structure are not particularly limited to those illustrated in FIGS. 9A and 9B. For example, the mesh structure may include only mesh lines extending in the first direction DR1 and the second direction DR2, or may include mesh lines extending in the first direction DR1, the second direction DR2, the first crossing direction CDR1, and the second crossing direction CDR2. That is, the mesh structure may be modified in various forms.

Meanwhile, in FIGS. 8A to 8C, the boundaries between the components are briefly illustrated by lines. That is, the lines illustrated in FIGS. 8A to 8C may be understood as corresponding to cutting lines along which the mesh structure illustrated in FIGS. 9A and 9B is cut, and in FIGS. 9A and 9B, the cutting lines are illustrated by dotted lines. Furthermore, even in the drawings that will be described below, the boundaries between components are briefly illustrated by lines. That is, the lines illustrated in the drawings that will be described below may be understood as corresponding to the cutting lines along which the mesh structure illustrated in FIGS. 9A and 9B is cut.

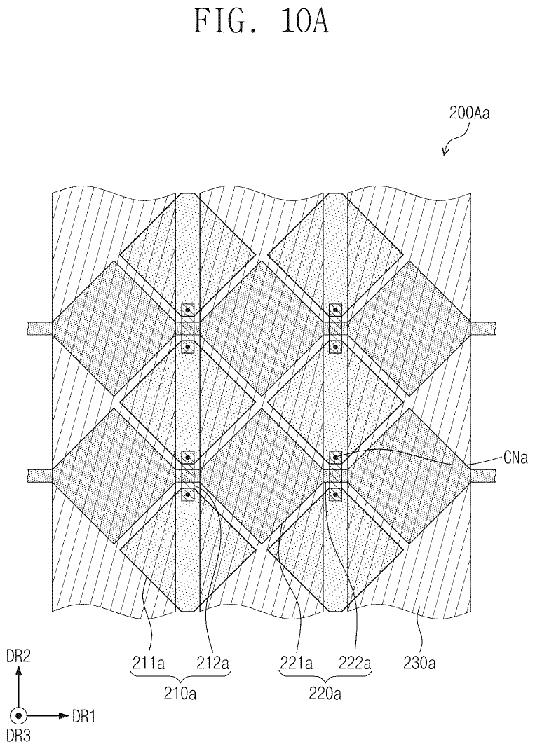

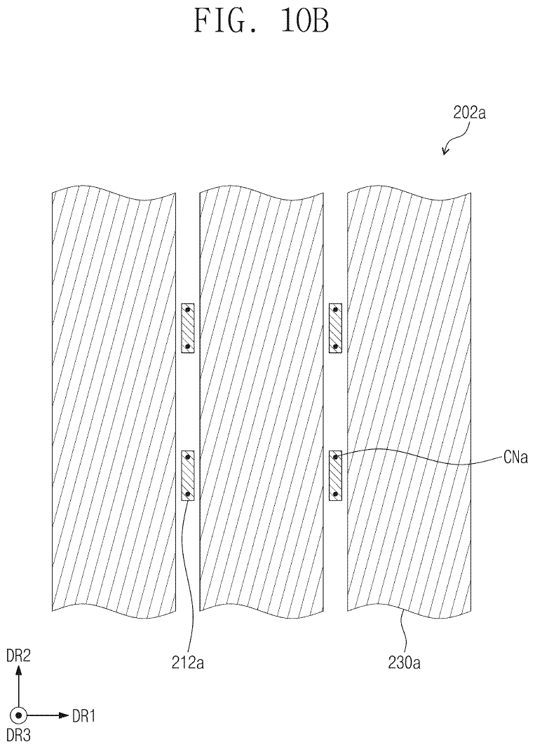

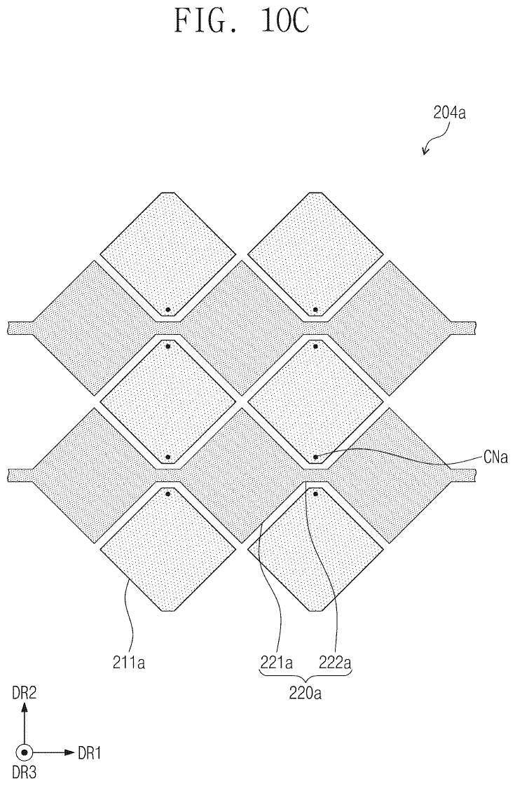

FIG. 10A is an enlarged plan view illustrating a portion of a sensing area 200Aa according to one or more embodiments of the present disclosure. FIG. 10B is a plan view illustrating a first conductive layer 202a of a portion of the sensing area 200Aa according to one or more embodiments of the present disclosure. FIG. 10C is a plan view illustrating a second conductive layer 204a of a portion of the sensing area 200Aa according to one or more embodiments of the present disclosure.

FIGS. 10A to 10C are enlarged views illustrating portions of two first electrodes 210a and two second electrodes 220a crossing each other, and portions of three third electrodes 230a overlapping the two first electrodes 210a.

Referring to FIGS. 10A to 10C, each of the first electrodes 210a may include first sensing patterns 211a and first bridge patterns 212a. The first sensing patterns 211a and the first bridge patterns 212a may be electrically connected with each other through contact holes CNa. For one first electrode 210a, the first sensing patterns 211a and the first bridge patterns 212a may be located on different layers so as to be spaced apart from each other.

Each of the second electrodes 220a may include second sensing patterns 221a and second bridge patterns 222a. For one second electrode 220a, the second sensing patterns 221a and the second bridge patterns 222a may form a one-body shape (e.g., may be integrally formed). In the case of the second sensing patterns 221a and the second bridge patterns 222a that form the one-body shape, the second sensing patterns 221a may be referred to as second sensing portions or second sensing parts, and the second bridge patterns 222a may be referred to as second bridge portions, second bridge parts, second connecting portions, or second connecting parts.

The second electrodes 220a may be located on the same layer as the first sensing patterns 211a. For example, the first sensing patterns 211a adjacent to each other in the second direction DR2 may be spaced apart from each other with one second electrode 220a therebetween. The first bridge patterns 212a may be located on a layer that is different from the layer on which the second electrodes 220a are located. The first bridge patterns 212a may be insulated from the second electrodes 220a, and may cross the second electrodes 220a.

The third electrodes 230a may be located on the same layer as the first bridge patterns 212a. Each of the third electrodes 230a may extend in the same direction as the extension direction of the first bridge pattern 212a. The third electrode 230a may extend in the same direction as the arrangement direction of the first sensing patterns 211a or the extension direction of the first electrode 210a. The third electrode 230a may extend in the second direction DR2. The extension direction of the third electrode 230a may be the same as the extension direction of the bridge pattern located on the same layer, the arrangement direction of the sensing patterns connected by the bridge pattern located on the same layer, or the extension direction of the electrode including the bridge pattern located on the same layer.

The third electrodes 230a may be spaced apart from the first bridge patterns 212a. The third electrodes 230a may alternate with the first bridge patterns 212a of the first electrodes 210a in the first direction DR1. The first bridge patterns 212a included in one first electrode 210a may be located between the third electrodes 230a adjacent to each other in the first direction DR1. In other words, the first bridge patterns 212a arranged in the second direction DR2 may be located between the third electrodes 230a adjacent to each other in the first direction DR1. Outer edges of the first bridge pattern 212a and the third electrode 230a adjacent to each other may face each other. In other words, a portion of the outer edges of the first bridge pattern 212a and a portion of the outer edge of the third electrode 230a adjacent to each other may face each other.

Each of the third electrodes 230a may have a bar shape extending in one direction. As the shape of an electrode is close to a bar shape, a resistance path may be shortened. Accordingly, the resistance of the third electrodes 230a may be decreased as the resistance path of the third electrodes 230a is shortened. As a result, the pen-sensing sensitivity of a sensor layer 200a may be improved.

Each of the third electrodes 230a may extend in the same direction as the extension direction of the bridge pattern located on the same layer. Accordingly, the third electrode 230a may be relatively wide while having a bar shape. That is, a space in which the third electrode 230a in a bar shape is capable of having an increased or maximum width may be provided.

In one or more embodiments, one portion of one third electrode 230a may overlap a portion of each of the first sensing patterns 211a included in one first electrode 210a, and another portion of the one third electrode 230a may overlap a portion of each of the first sensing patterns 211a included in another first electrode 210a. That is, one third electrode 230a may overlap portions of two first electrodes 210a. One portion of each of the first sensing patterns 211a included in one first electrode 210a may overlap a portion of one third electrode 230a, and another portion of each of the first sensing patterns 211a included in the one first electrode 210a may overlap a portion of another third electrode 230a. That is, one first electrode 210a may overlap portions of two third electrodes 230a.

The first bridge patterns 212a of the first electrodes 210a and the third electrodes 230a may be located on the same layer, and may include the same material. For example, the first bridge patterns 212a and the third electrodes 230a may be included in the first conductive layer 202a.

The first sensing patterns 211a of the first electrodes 210a and the second sensing patterns 221a and the second bridge patterns 222a of the second electrodes 220a may be located on the same layer, and may include the same material. For example, the first sensing patterns 211a and the second electrodes 220a may be included in the second conductive layer 204a. The first sensing patterns 211a and the first bridge patterns 212a may be electrically connected with each other through the contact holes CNa defined in the intermediate insulating layer 203.

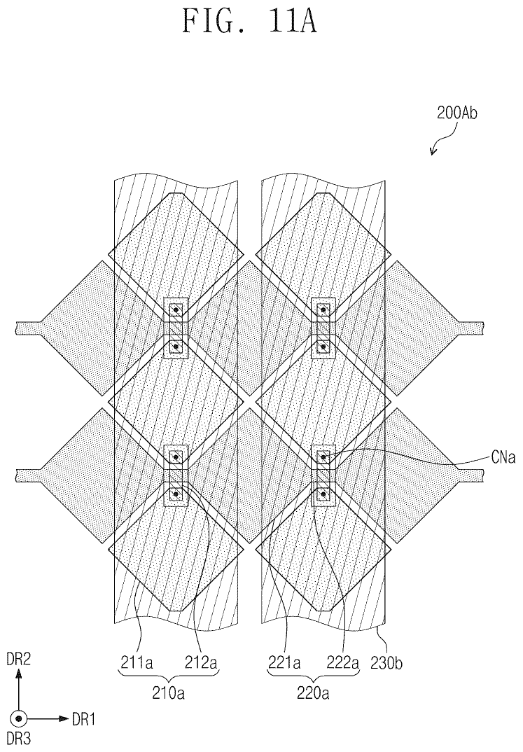

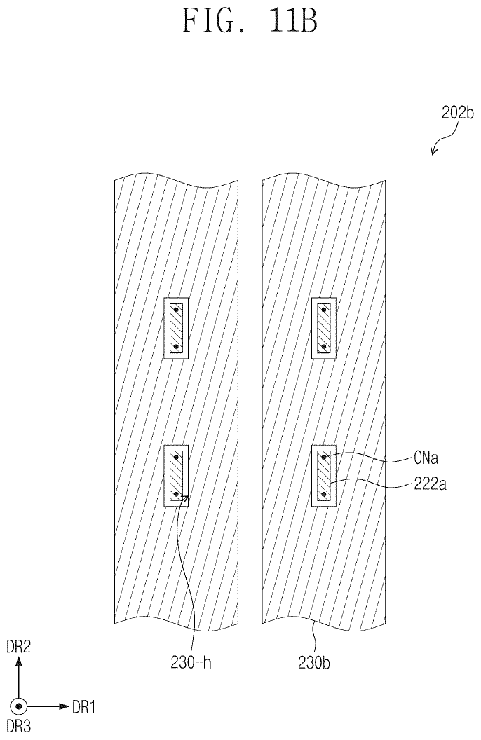

FIG. 11A is an enlarged plan view illustrating a portion of a sensing area 200Ab according to one or more embodiments of the present disclosure. FIG. 11B is a plan view illustrating a first conductive layer 202b of a portion of the sensing area 200Ab, according to one or more embodiments of the present disclosure.

FIGS. 11A and 11B are enlarged views illustrating portions of two first electrodes 210a and two second electrodes 220a crossing each other, and portions of two third electrodes 230b overlapping the two first electrodes 210a.

Referring to FIGS. 10C, 11A, and 11B, each of the first electrodes 210a may include first sensing patterns 211a and first bridge patterns 212a. The first sensing patterns 211a and the first bridge patterns 212a may be electrically connected with each other through contact holes CNa. Each of the second electrodes 220a may include second sensing patterns 221a and second bridge patterns 222a. For one second electrode 220a, the second sensing patterns 221a and the second bridge patterns 222a may form a one-body shape (e.g., may be integrally formed).

The third electrodes 230b may be located on the same layer as the first bridge patterns 212a. Each of the third electrodes 230b may extend in the same direction as the extension direction of the first bridge pattern 212a. The third electrode 230b may extend in the second direction DR2.

A hole 230-h may be defined in each of the third electrodes 230b. Each of the first bridge patterns 212a may be located in a corresponding hole 230-h, and may be insulated from the third electrode 230b. The first bridge pattern 212a may be surrounded by the corresponding hole 230-h. The outer edge of the first bridge pattern 212a may face the inner edge of the third electrode 230b that defines the corresponding hole 230-h.

One third electrode 230b may overlap one first electrode 210a. The third electrodes 230b may overlap the first electrodes 210a in a one-to-one correspondence.

In one or more embodiments, the third electrode 230b may serve to supplement a signal transferred from the first electrodes 210a to the sensor driver 200C (refer to FIG. 5). In this case, the greatest effect may be obtained when the phase of a signal induced in the third electrode 230b coincides with the phase of a signal induced in the first electrodes 210a. Accordingly, the centers of the first electrodes 210a in the second direction DR2 may overlap the centers of the third electrodes 230b in the second direction DR2. In addition, the centers of the first electrodes 210a in the first direction DR1 may overlap the centers of the third electrodes 230b in the first direction DR1. However, embodiments are not limited thereto.

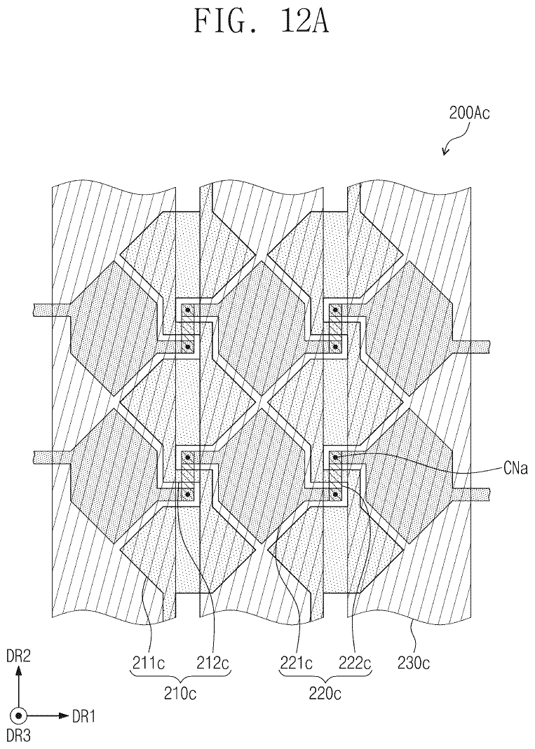

FIG. 12A is an enlarged plan view illustrating a portion of a sensing area 200Ac according to one or more embodiments of the present disclosure. FIG. 12B is a plan view illustrating a second conductive layer 204c of a portion of the sensing area 200Ac according to one or more embodiments of the present disclosure.

FIGS. 12A and 12B are enlarged views illustrating portions of two first electrodes 210c and two second electrodes 220c crossing each other, and portions of three third electrodes 230c overlapping the two first electrodes 210c.

Referring to FIGS. 12A 12B, each of the first electrodes 210c may include first sensing patterns 211c and first bridge patterns 212c. For one first electrode 210c, the first sensing patterns 211c and the first bridge patterns 212c may form a one-body shape (e.g., may be integrally formed).

Each of the first bridge patterns 212c may have a bent shape. For example, the first bridge pattern 212c may include a first line portion L1, a second line portion L2, and a third line portion L3. When one first bridge pattern 212c connects one first sensing pattern 211c and another first sensing pattern 211c that are adjacent to each other, the first line portion L1 may be a portion extending in the direction toward the other first sensing pattern 211c from one side of the one first sensing pattern 211c (e.g., in the second direction DR2). The third line portion L3 may be a portion extending in the direction toward the one first sensing pattern 211c from one side of the other first sensing pattern 211c (e.g., in the direction opposite to the second direction DR2). The second line portion L2 may be a portion that connects the first line portion L1 and the third line portion L3, and extends in the first direction DR1. A depression, or indentation (hereinafter, referred to as the first depression), may be provided in the first electrode 210c by the one first sensing pattern 211c and the first and second line portions L1 and L2. A depression, or indentation (hereinafter, referred to as the second depression), may be provided in the first electrode 210c by the other first sensing pattern 211c and the second and third line portions L2 and L3.

Each of the second electrodes 220c may include second sensing patterns 221c and second bridge patterns 222c. The second sensing patterns 221c and the second bridge patterns 222c may be electrically connected with each other through contact holes CNa.

Each of the second sensing patterns 221c may include a first protrusion X1 and a second protrusion X2. Each of the first protrusion X1 and the second protrusion X2 may extend in the first direction DR1. The first protrusion X1 may be located on one side of the second sensing pattern 221c in the first direction DR1, and the second protrusion X2 may be located on an opposite side of the second sensing pattern 221c in the first direction DR1. The first protrusion X1 may be located in the first depression of the adjacent first electrode 210c. The second protrusion X2 may be located in the second depression of the adjacent first electrode 210c.

Because each of the second sensing patterns 221c includes the first protrusion X1 and the second protrusion X2, each of the second bridge patterns 222c may extend in the second direction DR2. That is, for one second electrode 220c, each of the second bridge patterns 212c may extend in the direction perpendicular to the arrangement direction of the second sensing patterns 221c. Accordingly, each of the third electrodes 230c may extend in the second direction DR2 that is the same direction as the extension direction of the second bridge pattern 222c. The third electrode 230c may have a bar shape extending in the second direction DR2.

The extension direction of each of the third electrodes 230c may be the same as the extension direction of the bridge pattern located on the same layer, but may be perpendicular to the arrangement direction of the sensing patterns connected by the bridge pattern located on the same layer or the extension direction of the electrode including the bridge pattern located on the same layer. The third electrode 230c may extend in the same direction as the arrangement direction of the first sensing patterns 211c.

One portion of one third electrode 230c may overlap a portion of each of the first sensing patterns 211c included in one first electrode 210c, and another portion of the one third electrode 230c may overlap a portion of each of the first sensing patterns 211c included in another first electrode 210c.

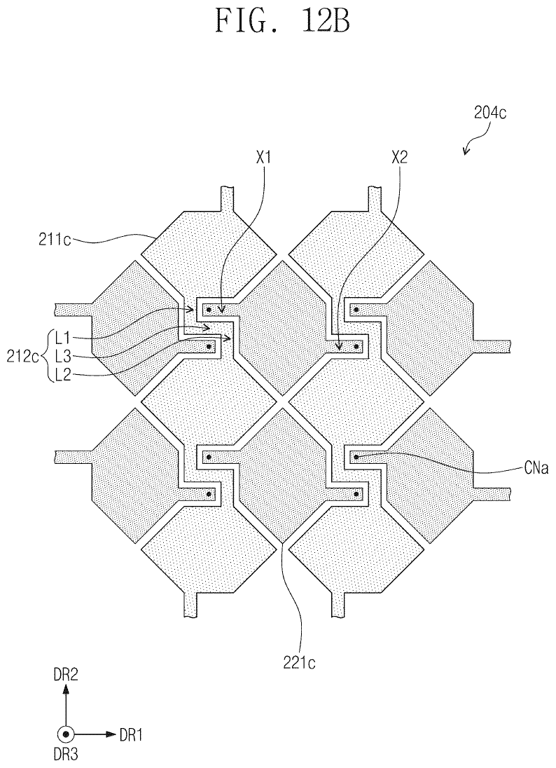

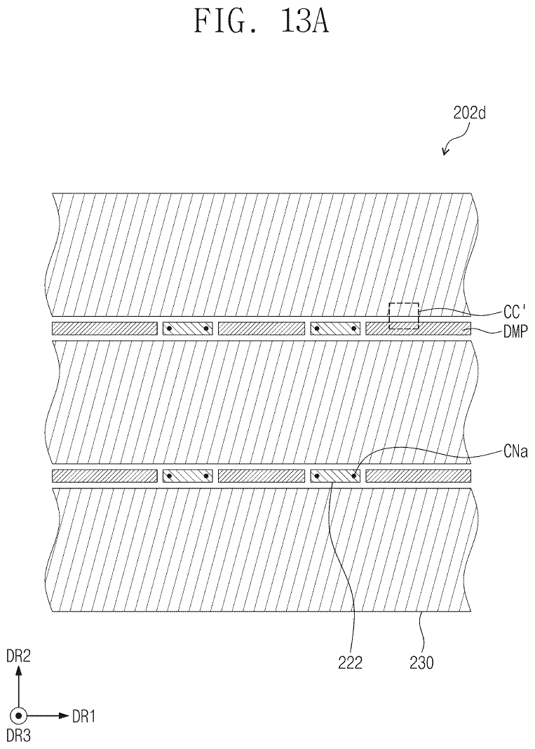

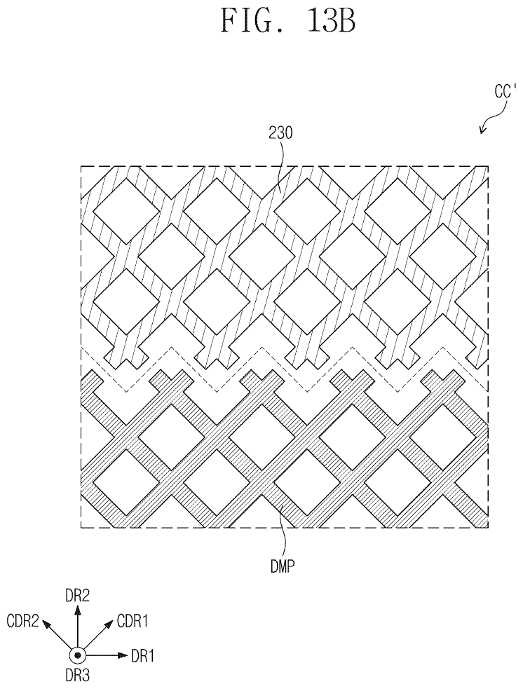

FIG. 13A is a plan view illustrating a first conductive layer 202d of a portion of the sensing area 200A (refer to FIG. 8A) according to one or more embodiments of the present disclosure. FIG. 13B is an enlarged plan view of area CC′ illustrated in FIG. 13A.

Referring to FIGS. 13A and 13B, the first conductive layer 202d may include the second bridge patterns 222 of the second electrodes 220 (refer to FIG. 8A) and the third electrodes 230. Each of the second bridge patterns 222 may extend in the first direction DR1. Each of the third electrodes 230 may extend in the first direction DR1 that is the same direction as the extension direction of the second bridge patterns 222.

The first conductive layer 202d may further include dummy patterns DMP. Each of the dummy patterns DMP may be floated or electrically floated. The dummy pattern DMP may be located between the third electrodes 230 adjacent to each other in the second direction DR2. In addition, the dummy pattern DMP may be located between the second bridge patterns 222 adjacent to each other in the first direction DR1.

According to one or more embodiments of the present disclosure, the dummy patterns DMP may be provided in the spaces where the electrodes are not located in the first conductive layer 202d. As illustrated in FIG. 13B, the dummy patterns DMP may also have a mesh structure. Accordingly, mesh lines may be entirely located in the sensing area 200A (refer to FIG. 8A), and thus the probability that patterns will be visually recognized due to reflection of external light may be decreased. That is, the electronic device 1000 (refer to FIG. 1A) in which visibility depending on reflection of external light is improved may be provided.

Meanwhile, according to one or more embodiments of the present disclosure, the second conductive layer 204 (refer to FIG. 8C) may also further include dummy patterns. That is, the dummy patterns may be provided in the spaces where the electrodes are not located in the second conductive layer 204 (refer to FIG. 8C). For example, the dummy patterns may be located between the first electrodes 210 (refer to FIG. 8C) and the second sensing patterns 221 (refer to FIG. 8C) adjacent to each other.

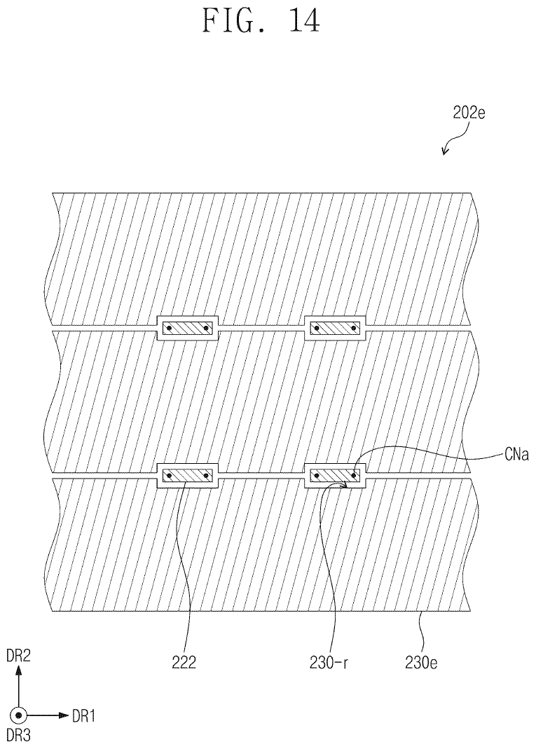

FIG. 14 is a plan view illustrating a first conductive layer 202e of a portion of the sensing area 200A (refer to FIG. 8A) according to one or more embodiments of the present disclosure.

Referring to FIG. 14, the first conductive layer 202e may include the second bridge patterns 222 of the second electrodes 220 (refer to FIG. 8A) and third electrodes 230e. Each of the second bridge patterns 222 may extend in the first direction DR1. Each of the third electrodes 230e may extend in the first direction DR1 that is the same direction as the extension direction of the second bridge patterns 222.

Depressions 230-r (or, concave portions) may be defined in the third electrodes 230e, respectively. Each of the depressions 230-r may be a portion recessed or indented in the direction perpendicular to the extension direction of the second bridge patterns 222 (e.g., in the second direction DR2). The depressions 230-r defined in the third electrodes 230e adjacent to each other in the second direction DR2 may face each other, and may provide the space in which each of the second bridge patterns 222 is located. That is, at least a portion of each of the second bridge patterns 222 may be located in the depressions 230-r of the third electrodes 230e that face each other.

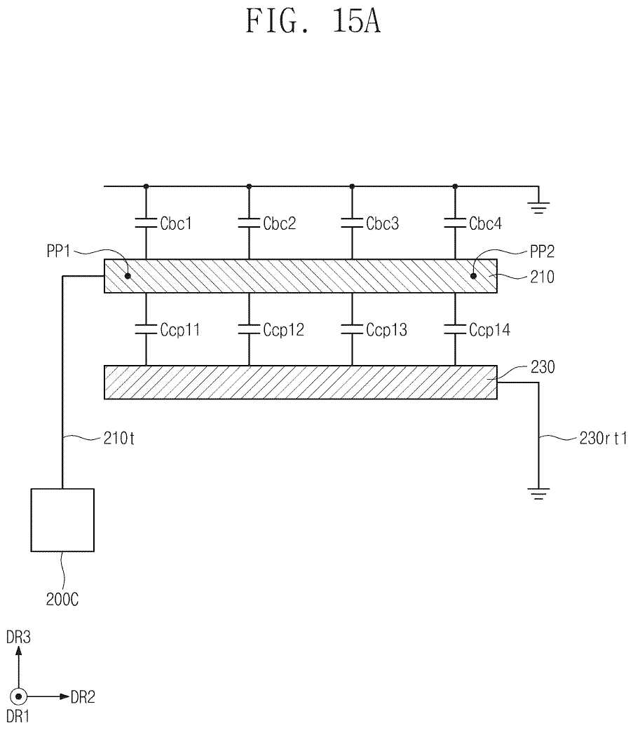

FIG. 15A is a schematic view illustrating one channel according to one or more embodiments of the present disclosure. FIG. 15B is an equivalent circuit diagram illustrating a relationship between the one channel and the pen according to one or more embodiments of the present disclosure.

Referring to FIGS. 7, 15A, and 15B, the first electrodes 210 and the third electrodes 230 overlapping the first electrodes 210 when viewed in the third direction DR3 are illustrated. In FIGS. 15A and 15B, one first electrode 210 and one third electrode 230 at least partially overlapping each other are schematically illustrated.

One end of the third electrode 230 may be floated, and an opposite end of the third electrode 230 may be grounded. For example, the opposite end of the third electrode 230 may be electrically connected to the third trace line 230rt1, and the third trace line 230rt1 may be grounded. However, the present disclosure is not particularly limited thereto. For example, the third trace line 230rt1 may be grounded through a bias capacitor.

Capacitors Cbc1, Cbc2, Cbc3, and Cbc4 may be defined in the first electrode 210. The capacitors Cbc1, Cbc2, Cbc3, and Cbc4 may be referred to as parasitic capacitors or base capacitors. According to one or more embodiments of the present disclosure, the capacitors Cbc1, Cbc2, Cbc3, and Cbc4 may also be used to increase the magnitude of a signal.

When the pen PN closely approaches the first electrode 210, a first induced electromotive force Vs (t) and a second induced electromotive force Va (t) may be generated in the first electrode 210 and the third electrode 230, respectively, by a magnetic field generated from the pen PN. A first induced current IN-M and a third induced current IN-B may be generated by the first induced electromotive force Vs(t), and a second induced current IN-A may be generated by the second induced electromotive force Va(t). Accordingly, the total induced current IN input to an input terminal IT may correspond to the sum of the first to third induced currents IN-M, IN-A, and IN-B.

For example, it is assumed that the capacitance of each of the capacitors Cbc1, Cbc2, Cbc3, and Cbc4 is Cb and the capacitance of each of first coupling capacitors Ccp11, Ccp12, Ccp13, and Ccp14 is Cc.

The first induced current IN-M over time may be expressed by the equation below.

$$3 Cb \frac{dVs ( t )}{dt}$$

The second induced current IN-A over time may be expressed by the equation below.

$$Cc \frac{dVa ( t )}{dt}$$

The third induced current IN-B over time may be expressed by the equation below.

$$3 Cc \frac{dVs ( t )}{dt}$$

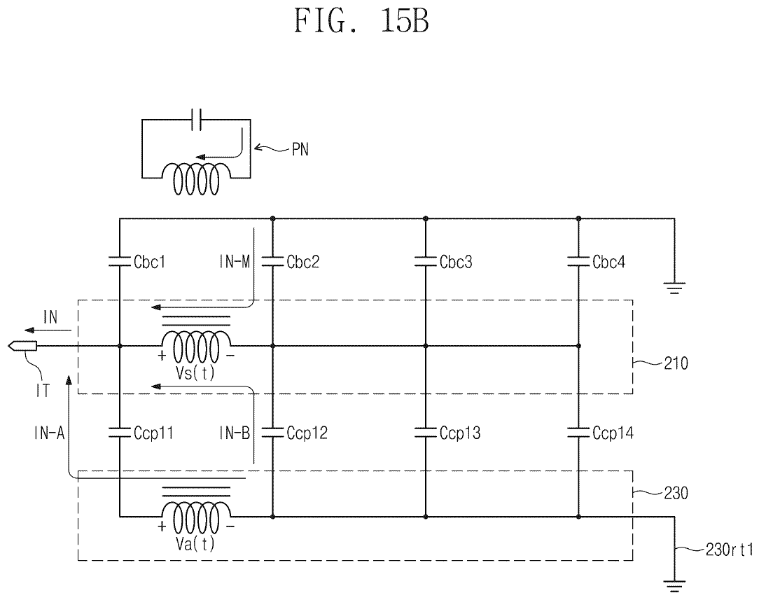

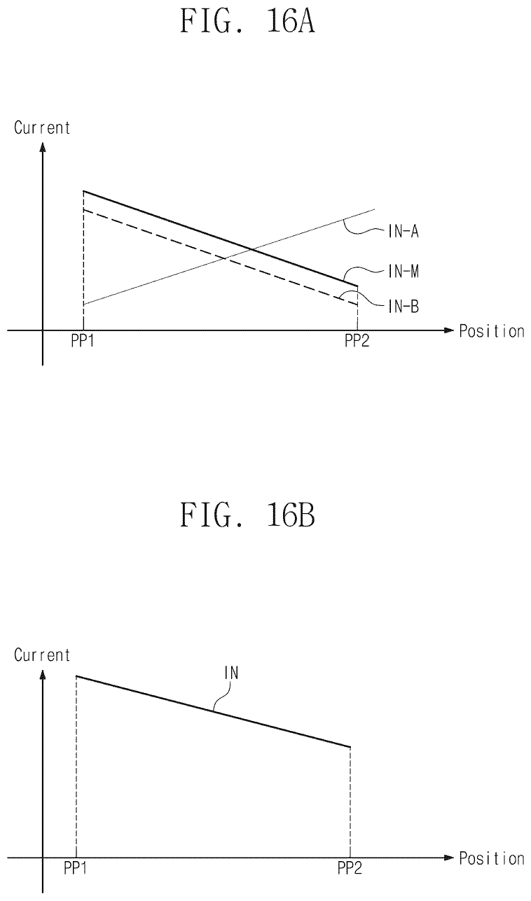

FIG. 16A is a graph depicting the magnitudes of the currents depending on the position of the pen relative to the one channel. FIG. 16B is a graph depicting the magnitude of a signal depending on the position of the pen relative to the one channel.

Referring to FIGS. 15A, 15B, and 16A, the opposite ends of capacitors located between the input terminal IT and the pen PN among the capacitors Cbc1, Cbc2, Cbc3, and Cbc4 may all be grounded, and therefore current may not flow. Accordingly, when the position of the pen PN moves from a first point PP1 to a second point PP2, the first induced current IN-M may be gradually decreased. In addition, the second induced current IN-A may be gradually increased, and the third induced current IN-B may be gradually decreased.

Referring to FIGS. 15A, 15B, and 16B, when the position of the pen PN moves from the first point PP1 to the second point PP2, the total induced current IN may be gradually decreased. However, as described above, the total induced current IN may correspond to the sum of the first to third induced currents IN-M, IN-A, and IN-B, and the magnitude of the total induced current IN at the second point PP2 may be secured to be greater than or equal to a certain value.

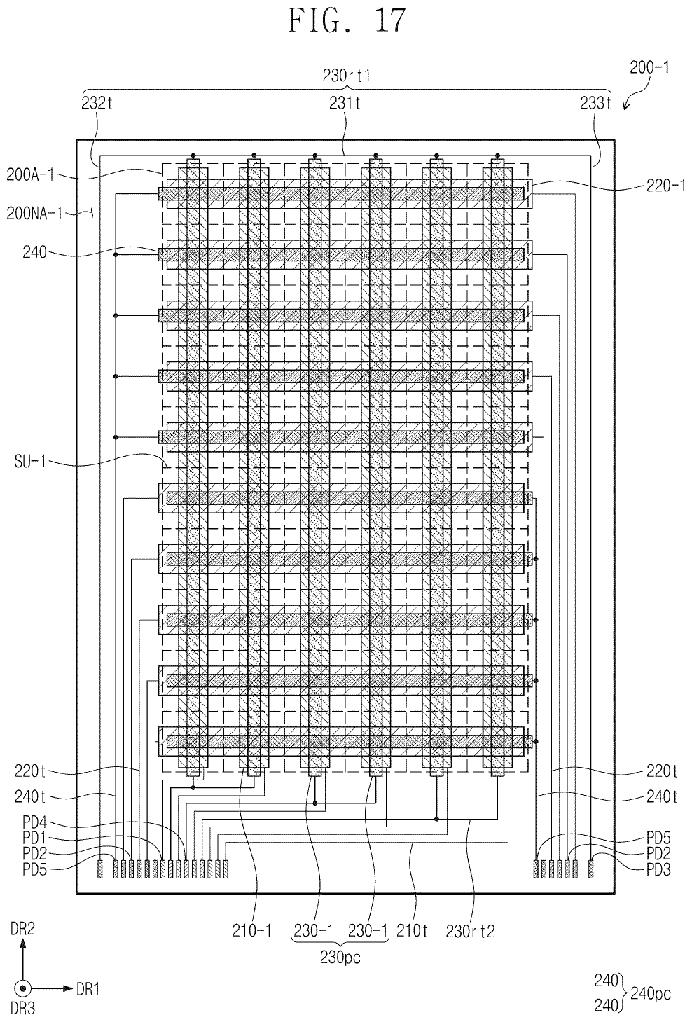

FIG. 17 is a plan view of a sensor layer 200-1 according to one or more embodiments of the present disclosure.

Referring to FIG. 17, a sensing area 200A-1 and a peripheral area 200NA-1 adjacent to the sensing area 200A-1 may be defined in the sensor layer 200-1.

The sensor layer 200-1 may include a plurality of first electrodes 210-1, a plurality of second electrodes 220-1, a plurality of third electrodes 230-1, and a plurality of fourth electrodes 240 located in the sensing area 200A-1. That is, the sensor layer 200-1 may further include the fourth electrodes 240 when compared to the sensor layer 200 described above with reference to FIG. 7. A sensing unit SU-1 of the sensor layer 200-1 may be an area where one first electrode 210-1 and one second electrode 220-1 cross each other.

The fourth electrodes 240 may be arranged in the second direction DR2. Each of the fourth electrodes 240 may extend in the first direction DR1. One fourth electrode 240 may at least partially overlap one second electrode 220-1. According to one or more embodiments of the present disclosure, the capacitance (or, coupling capacitance) between one second electrode 220-1 and one fourth electrode 240 may be adjusted by adjusting the overlapping area between the one second electrode 220-1 and the one fourth electrode 240. Alternatively, according to one or more embodiments of the present disclosure, one second electrode 220-1 may overlap a plurality of (e.g., two) fourth electrodes 240. In this case, the capacitance (or, coupling capacitance) between the one second electrode 220-1 and the plurality of fourth electrodes 240 may be adjusted by adjusting the overlapping area between the one second electrode 220-1 and the plurality of fourth electrodes 240.

Although FIG. 17 illustrates an example that the third electrodes 230-1 overlap the first electrodes 210-1 in a one-to-one correspondence, and the fourth electrodes 240 overlap the second electrodes 220-1 in a one-to-one correspondence, this is illustrative, and embodiments are not limited thereto. For example, one third electrode 230-1 may overlap a plurality of first electrodes 210-1. Alternatively, one fourth electrode 240 may overlap a plurality of second electrodes 220-1.

In one or more embodiments of the present disclosure, at least some of the fourth electrodes 240 may be electrically connected to form one fourth electrode group 240pc. FIG. 17 illustrates an example that five fourth electrodes 240 are connected to the same trace line to form one fourth electrode group 240pc. Accordingly, in FIG. 17, two fourth electrode groups 240pc are illustrated as being arranged in the second direction DR2. However, the number of fourth electrodes 240 constituting one fourth electrode group 240pc is not limited thereto. For example, the number of fourth electrodes 240 constituting one fourth electrode group 240pc may be 10, and in this case, the sensor layer 200-1 may include only the one fourth electrode group 240pc.

The sensor layer 200-1 may further include a third trace line 230rt1 located in the peripheral area 200NA-1, a plurality of third pads PD3 connected to one end and an opposite end of the third trace line 230rt1, fourth trace lines 230rt2, fourth pads PD4 connected to the fourth trace lines 230rt2 in a one-to-one correspondence, fifth trace lines 240t, and fifth pads PD5 connected to the fifth trace lines 240t in a one-to-one correspondence. That is, when compared to the sensor layer 200 described above with reference to FIG. 7, the sensor layer 200-1 may further include the fifth trace lines 240t, and the fifth pads PD5 connected to the fifth trace lines 240t in a one-to-one correspondence.

The fifth trace lines 240t may be spaced apart from each other with the sensing area 200A-1 therebetween. The fifth trace lines 240t may be electrically connected to the fourth electrode groups 240pc in a one-to-one correspondence. FIG. 17 illustrates an example that two fourth electrode groups 240pc are arranged, and two fifth trace lines 240t are connected to the two fourth electrode groups 240pc, respectively. The fifth trace line 240t connected to one fourth electrode group 240pc, and the fifth trace line 240t connected to the other fourth electrode group 240pc, may be spaced apart from each other with the sensing area 200A-1 therebetween. However, the present disclosure is not particularly limited thereto.

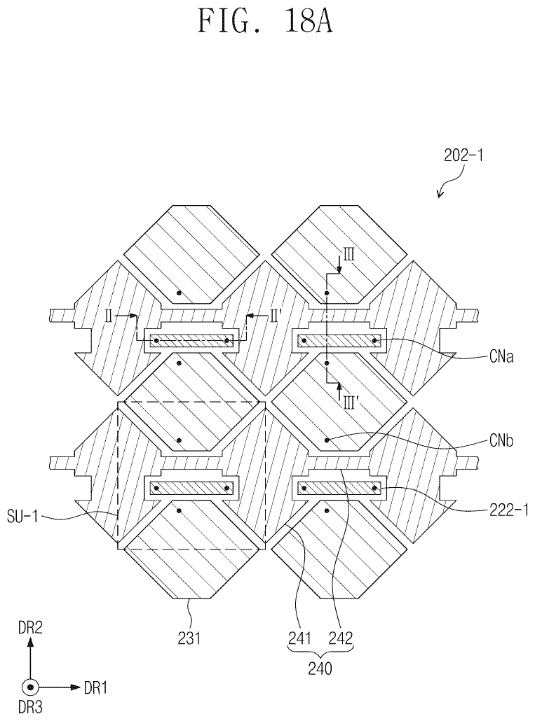

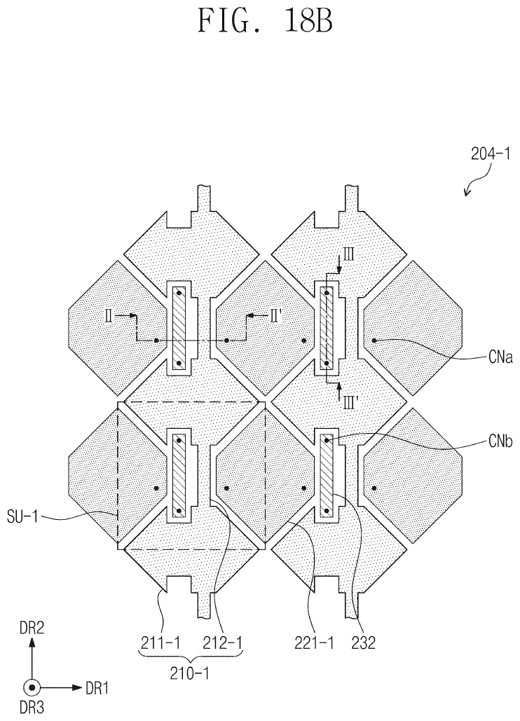

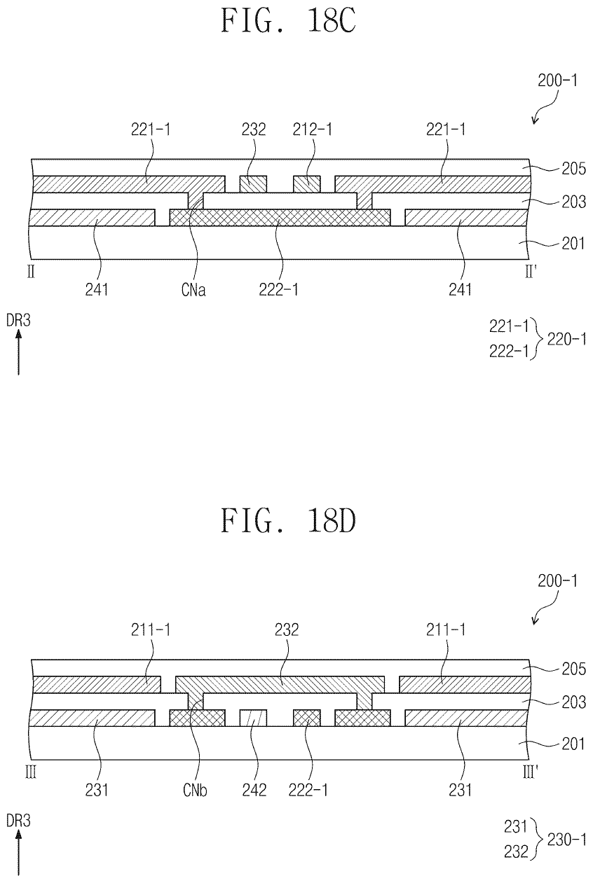

FIG. 18A is a plan view illustrating a first conductive layer 202-1 of a portion of the sensing area 200A-1 (refer to FIG. 17) according to one or more embodiments of the present disclosure. FIG. 18B is a plan view illustrating a second conductive layer 204-1 of a portion of the sensing area 200A-1 (refer to FIG. 17) according to one or more embodiments of the present disclosure. FIG. 18C is a sectional view of the sensor layer 200-1 taken along the line II-II′ illustrated in FIGS. 18A and 18B according to one or more embodiments of the present disclosure. FIG. 18D is a sectional view of the sensor layer 200-1 taken along the line III-III′ illustrated in FIGS. 18A and 18B according to one or more embodiments of the present disclosure.

FIG. 18A is an enlarged view illustrating portions of two first electrodes 210-1 and two second electrodes 220-1 crossing each other, and FIG. 18B is an enlarged view illustrating portions of two third electrodes 230-1 and two fourth electrodes 240 crossing each other.

Referring to FIGS. 18A to 18D, each of the first electrodes 210-1 may include first sensing patterns 211-1 and first bridge patterns 212-1. In one first electrode 210-1, the first sensing patterns 211-1 may be arranged in the second direction DR2, and each of the first bridge patterns 212-1 may be located between the first sensing patterns 211-1 to connect the adjacent first sensing patterns 211-1. The first bridge pattern 212-1 may extend in the second direction DR2. For one first electrode 210-1, the first sensing patterns 211-1 and the first bridge patterns 212-1 may form a one-body shape (e.g., may be integrally formed).

Each of the second electrodes 220-1 may include second sensing patterns 221-1 and second bridge patterns 222-1. In one second electrode 220-1, the second sensing patterns 221-1 may be arranged in the first direction DR1, and each of the second bridge patterns 222-1 may connect the adjacent second sensing patterns 221. For one second electrode 220-1, the second sensing patterns 221-1 and the second bridge patterns 222-1 may be located on different respective layers so as to be spaced apart from each other. The second sensing patterns 221-1 and the second bridge patterns 222-1 may be electrically connected with each other through contact holes CNa penetrating an intermediate insulating layer 203. Each of the second bridge patterns 222-1 may extend in the first direction DR1.

Each of the third electrodes 230-1 may include third sensing patterns 231 and third bridge patterns 232. In one third electrode 230, the third sensing patterns 231 may be arranged in the second direction DR2, and each of the third bridge patterns 232 may connect the adjacent third sensing patterns 231. For one third electrode 230-1, the third sensing patterns 231 and the third bridge patterns 232 may be located on different layers so as to be spaced apart from each other. The third sensing patterns 231 and the third bridge patterns 232 may be electrically connected with each other through contact holes CNb penetrating the intermediate insulating layer 203. Each of the third bridge patterns 232 may extend in the second direction DR2.

Each of the fourth electrodes 240 may include fourth sensing patterns 241 and fourth bridge patterns 242. In one fourth electrode 240, the fourth sensing patterns 241 may be arranged in the first direction DR1, and each of the fourth bridge patterns 242 may be located between the fourth sensing patterns 241 to connect the adjacent fourth sensing patterns 241. The fourth bridge pattern 242 may extend in the first direction DR1. For one fourth electrode 240, the fourth sensing patterns 241 and the fourth bridge patterns 242 may form a one-body shape (e.g., may be integrally formed). The pen-sensing electrodes may include first pen-sensing electrodes and second pen-sensing electrodes. The third electrodes 230-1 may be referred to as the first pen-sensing electrodes, and the fourth electrodes 240 may be referred to as the second pen-sensing electrodes. Alternatively, auxiliary electrodes may include first auxiliary electrodes and second auxiliary electrodes. The third electrodes 230-1 may be referred to as the first auxiliary electrodes, and the fourth electrodes 240 may be referred to as the second auxiliary electrodes.

As illustrated in FIGS. 18B to 18D, the first electrodes 210-1 and the second sensing patterns 221-1 may be located on the same layer. In addition, the third bridge patterns 232 may be located on the same layer as the first electrodes 210-1 and the second sensing patterns 221-1. For example, the first electrodes 210-1, the second sensing patterns 221-1, and the third bridge patterns 232 may be included in the second conductive layer 204-1.

Each of the third bridge patterns 232 may extend in the same direction as the extension direction of the first bridge patterns 212-1. The third bridge pattern 232 may extend in the same direction as the arrangement direction of the first sensing patterns 211-1 in one first electrode 210-1 or in the extension direction of the one first electrode 210-1.

The third bridge patterns 232 may be spaced apart from the first electrodes 210-1 and the second sensing patterns 221-1, and may be insulated from the first electrodes 210-1 and the second sensing patterns 221-1. Outer edges of the third bridge pattern 232 and the first electrode 210-1 adjacent to each other may face each other. In other words, a portion of the outer edge of the third bridge pattern 232 and a portion of the outer edge of the first electrode 210-1 adjacent to each other may face each other.

In one or more embodiments, each of the third bridge patterns 232 may extend parallelly to a corresponding first bridge pattern 212-1. For example, the third bridge pattern 232 may be spaced apart from the corresponding first bridge pattern 212-1 in the first direction DR1, and may be located between two first sensing patterns 211-1 connected by the corresponding first bridge pattern 212-1. Accordingly, other types of bridge patterns (that is, the first and third bridge patterns 212-1 and 232) that are located in the same layer, and that extend in the same direction, may be located such that outer edges face each other. To provide the space in which the third bridge patterns 232 are located, a hole may not be formed in the first bridge patterns 212-1 (or, the first electrodes 210-1), and an increase in the resistance of the first electrode 210-1 may be reduced or minimized.

In one or more embodiments, depressions (or, concave portions) may be defined in the first sensing patterns 211-1, respectively. Each of the depressions in the first sensing pattern 211-1 may be a portion recessed in the extension direction of the third bridge patterns 232. The depressions defined in the first sensing patterns 211-1 adjacent to each other in the second direction DR2 may face each other, and may provide the space in which each of the third bridge patterns 232 is located.

As illustrated in FIGS. 18A, 18C, and 18D, the third sensing patterns 231 and the fourth electrodes 240 may be located on the same layer. In addition, the second bridge patterns 222-1 may be located on the same layer as the third sensing patterns 231 and the fourth electrodes 240. For example, the second bridge patterns 222-1, the third sensing patterns 231, and the fourth electrodes 240 may be included in the first conductive layer 202-1.

Each of the second bridge patterns 222-1 may extend in the same direction as the extension direction of the fourth bridge patterns 242. The second bridge pattern 222-1 may extend in the same direction as the arrangement direction of the fourth sensing patterns 241 in one fourth electrode 240 or in the extension direction of the one fourth electrode 240.

The second bridge patterns 222-1 may be spaced apart from the third sensing patterns 231 and the fourth electrodes 240, and may be insulated from the third sensing patterns 231 and the fourth electrodes 240. Outer edges of the second bridge pattern 222-1 and the fourth electrode 240 adjacent to each other may face each other. In other words, a portion of the outer edge of the second bridge pattern 222-1 and a portion of the outer edge of the fourth electrode 240 adjacent to each other may face each other.

In one or more embodiments, each of the second bridge patterns 222-1 may extend in parallel to a corresponding fourth bridge pattern 242. For example, the second bridge pattern 222-1 may be spaced apart from the corresponding fourth bridge pattern 242 in the second direction DR2, and may be located between two fourth sensing patterns 241 connected by the corresponding fourth bridge pattern 242. Accordingly, other types of bridge patterns (that is, the second and fourth bridge patterns 222-1 and 242) that are located in the same layer and that extend in the same direction may be located such that outer edges face each other. To provide the space in which the second bridge patterns 222-1 are located, a hole may not be formed in the fourth bridge patterns 214 (or, the fourth electrodes 240), and an increase in the resistance of the fourth electrode 240 may be reduced or minimized.

In one or more embodiments, depressions (or, concave portions) may be defined in the fourth sensing patterns 241, respectively. Each of the depressions in the fourth sensing pattern 241 may be a portion recessed in the extension direction of the second bridge patterns 222-1. The depressions defined in the fourth sensing patterns 241 adjacent to each other in the first direction DR1 may face each other, and may provide the space in which each of the second bridge patterns 222-1 is located.

The third sensing patterns 231 in one third electrode 230-1 may overlap one first electrode 210-1. The third sensing patterns 231 in one third electrode 230-1 may overlap the first sensing patterns 211-1 in one first electrode 210-1, respectively. The third electrodes 230-1 may overlap the first electrodes 210-1 in a one-to-one correspondence. The term “overlap” used herein also means that at least a portion of one third electrode 230-1 overlaps at least a portion of one first electrode 210-1.

One fourth electrode 240 may overlap the second sensing patterns 221-1 in one second electrode 220-1. The fourth sensing patterns 241 in one fourth electrode 240 may overlap the second sensing patterns 221-1 in one second electrode 220-1, respectively. The fourth electrodes 240 may overlap the second electrodes 220 in a one-to-one correspondence. The term “overlap” used herein also means that at least a portion of one fourth electrode 240 overlaps at least a portion of one second electrode 220-1.

One third electrode 230-1 and one fourth electrode 240 crossing each other may be located in one sensing unit SU-1 where one first electrode 210-1 and one second electrode 220-1 cross each other.

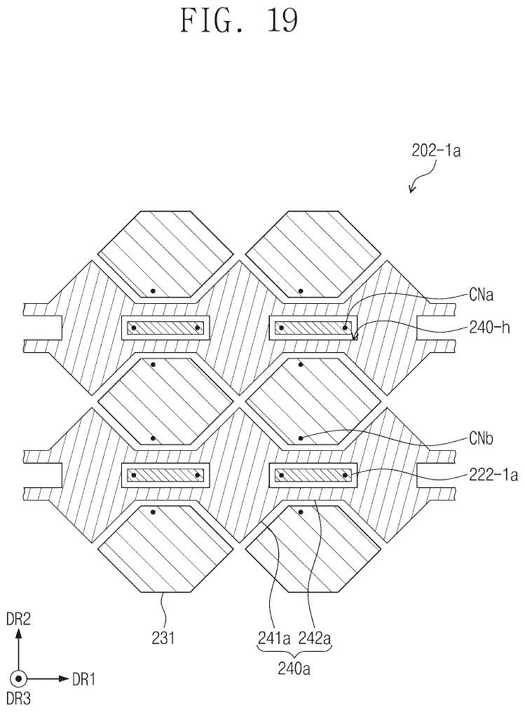

FIG. 19 is a plan view illustrating a first conductive layer 202-1a of a portion of the sensing area 200A-1 (refer to FIG. 17) according to one or more embodiments of the present disclosure.

Referring to FIG. 19, second bridge patterns 222-1a, third sensing patterns 231, and fourth electrodes 240a may be located on the same layer, and may include the same material. For example, the second bridge patterns 222-1a, the third sensing patterns 231, and the fourth electrodes 240a may be included in the first conductive layer 202-1a.

Each of the fourth electrodes 240a may include fourth sensing patterns 241a and fourth bridge patterns 242a. For one fourth electrode 240a, the fourth sensing patterns 241a and the fourth bridge patterns 242a may form a one-body shape (e.g., may be integrally formed).

A hole 240-h may be defined in each of the fourth electrodes 240a. For example, the hole 240-h may be defined in each of the fourth bridge patterns 242a. Each of the second bridge patterns 222-1a may be located in a corresponding hole 240-h, and may be insulated from the fourth electrode 240a. The second bridge pattern 222-1a may be surrounded by the corresponding hole 240-h. The outer edge of the second bridge pattern 222-1a may face the inner edge of the fourth electrode 240a that defines the corresponding hole 240-h.

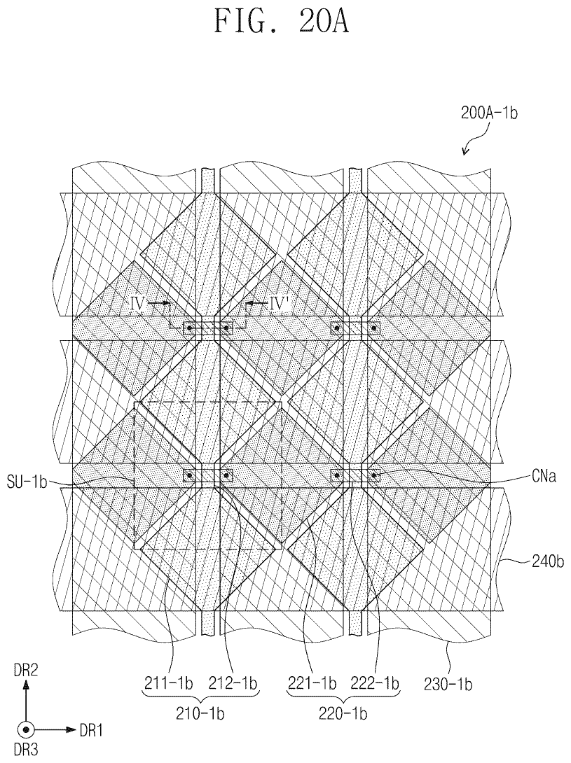

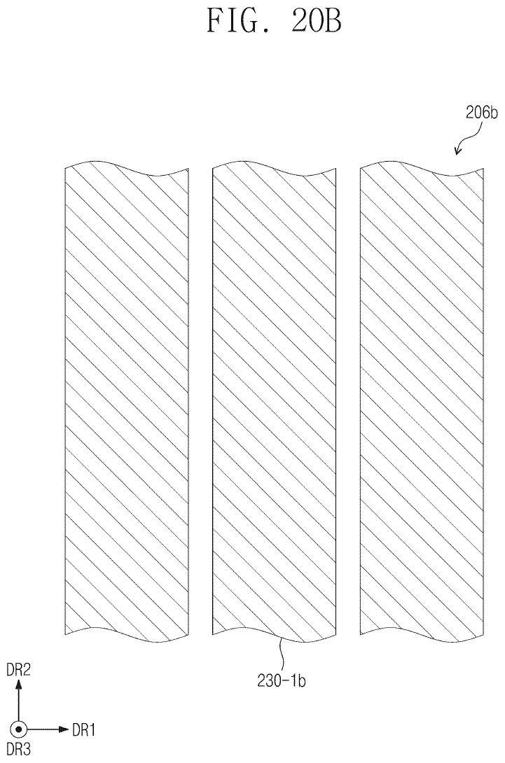

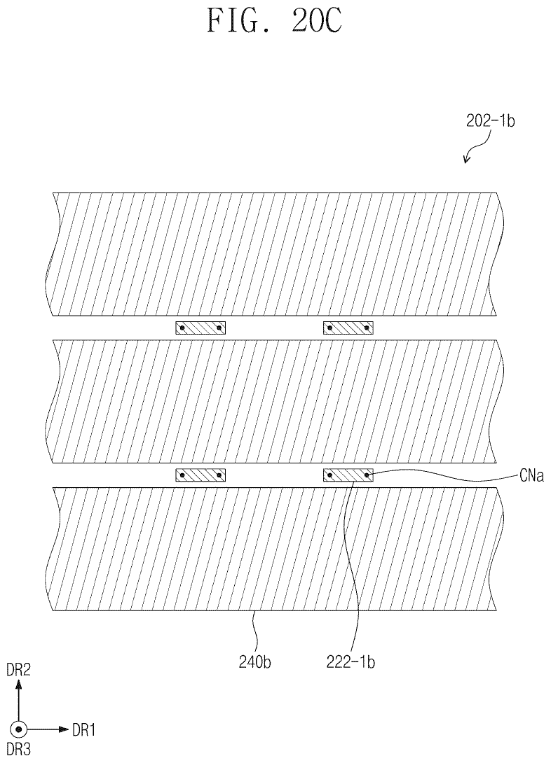

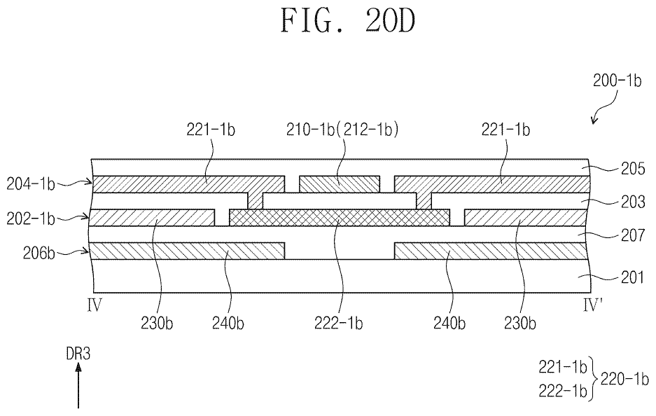

FIG. 20A is an enlarged plan view illustrating a portion of a sensing area 200A-1b according to one or more embodiments of the present disclosure. FIG. 20B is a plan view illustrating a lower conductive layer 206b of a portion of the sensing area 200A-1b according to one or more embodiments of the present disclosure. FIG. 20C is a plan view illustrating a first conductive layer 202-1b of a portion of the sensing area 200A-1b according to one or more embodiments of the present disclosure. FIG. 20D is a sectional view of a sensor layer taken along the line IV-IV′ illustrated in FIG. 20A according to one or more embodiments of the present disclosure.

FIGS. 20A to 20C are enlarged views illustrating portions of two first electrodes 210-1b and two second electrodes 220-1b crossing each other, portions of three third electrodes 230-1b overlapping the two first electrodes 210-1b, and portions of three fourth electrodes 240b overlapping the two second electrodes 220-1b.

Referring to FIGS. 20A to 20D, each of the first electrodes 210-1b may include first sensing patterns 211-1b and first bridge patterns 212-1b. For one first electrode 210-1b, the first sensing patterns 211-1b and the first bridge patterns 212-1b may form a one-body shape (e.g., may be integrally formed). Each of the second electrodes 220-1b may include second sensing patterns 221-1b and second bridge patterns 222-1b. The second sensing patterns 221-1b and the second bridge patterns 222-1b may be electrically connected with each other through contact holes CNa.

The first electrodes 210-1b and the second sensing patterns 221-1b may be located on the same layer. For example, the first electrodes 210-1b and the second sensing patterns 221-1b may be included in a second conductive layer 204-1b.

Meanwhile, the sensor layer 200-1b may include a base layer 201, the lower conductive layer 206b, a lower insulating layer 207, the first conductive layer 202-1b, an intermediate insulating layer 203, the second conductive layer 204-1b, and a cover insulating layer 205. That is, when compared to the sensor layer 200 described above with reference to FIGS. 8A to 8D, the sensor layer 200-1b may further include the lower conductive layer 206b and the lower insulating layer 207. That is, the sensor layer 200-1b may include three conductive layers. The lower insulating layer 207 may be located between the base layer 201 and the intermediate insulating layer 203, and the lower conductive layer 206b may be located on the base layer 201, and may be covered by the lower insulating layer 207. Meanwhile, in some embodiments, the lower conductive layer 206b may be omitted from the sensor layer 200-1b. For example, the lower conductive layer 206b may be located under the display layer 100 (refer to FIG. 4), or may be included in the display layer 100 (refer to FIG. 4).

The third electrodes 230-1b may be located on a layer that is different from the layers on which the first electrodes 210-1b, the second electrodes 220-1b, and the fourth electrodes 240b are located. For example, the third electrodes 230-1b may be included in the lower conductive layer 206b. Each of the third electrodes 230-1b may extend in the second direction DR2. The third electrode 230-1b may have a bar shape extending in the second direction DR2. When the third electrodes 230-1b are implemented with a separate conductive layer, such as the lower conductive layer 206b, the shape of the third electrodes 230-1b may be more freely designed. For example, the third electrodes 230-1b may be more densely provided using the lower conductive layer 206b, and in this case, the pen-sensing sensitivity may be improved.

The second bridge patterns 222-1b may be located on a layer that is different from the layer on which the first electrodes 210-1b and the second sensing patterns 221-1b are located. The second bridge patterns 222-1b may be located on the same layer as the fourth electrodes 240b. For example, the second bridge patterns 222-1b and the fourth electrodes 240b may be included in the first conductive layer 202-1b. Each of the second bridge patterns 222-1b may extend in the first direction DR1.

Each of the fourth electrodes 240b may extend in the same direction as the extension direction of the second bridge pattern 222-1b. The fourth electrode 240b may extend in the same direction as the arrangement direction of the second sensing patterns 221-1b or the extension direction of the second electrode 220-1b. The fourth electrode 240b may extend in the first direction DR1. The fourth electrode 240b may have a bar shape extending in the first direction DR1. The extension direction of the fourth electrode 240b may be the same as the extension direction of the bridge pattern located on the same layer, the arrangement direction of the sensing patterns connected by the bridge pattern located on the same layer, or the extension direction of the electrode including the bridge pattern located on the same layer.

The fourth electrodes 240b may be spaced apart from the second bridge patterns 222-1b. The second bridge patterns 222-1b included in one second electrode 220-1b may be located between the fourth electrodes 240b adjacent to each other in the second direction DR2. In other words, the second bridge patterns 222-1b arranged in the first direction DR1 may be located between the fourth electrodes 240b adjacent to each other in the second direction DR2. Outer edges of the second bridge pattern 222-1b and the fourth electrode 240b adjacent to each other may face each other. In other words, a portion of the outer edge of the second bridge pattern 222-1b and a portion of the outer edge of the fourth electrode 240b adjacent to each other may face each other.

Each of the fourth electrodes 240b may have a bar shape extending in one direction. As the shape of an electrode is close to a bar shape, a resistance path may be shortened. Accordingly, the resistance of the fourth electrodes 240b may be decreased as the resistance path of the fourth electrodes 240b is shortened. As a result, the pen-sensing sensitivity of the sensor layer 200-1b may be improved.

Each of the fourth electrodes 240b may extend in the same direction as the extension direction of the bridge pattern that is located on the same layer. Accordingly, the fourth electrode 240b may be designed to be relatively wide while having a bar shape. That is, a space in which the fourth electrode 240b in a bar shape is capable of having an increased or maximum width may be provided. When each of the fourth electrodes extends in the direction perpendicular to the extension direction of the bridge pattern that is located on the same layer, unlike the width of the fourth electrode, the bridge pattern may be relatively narrow due to the length of the bridge pattern in the extension direction.

One third electrode 230-1b may overlap each of the sensing patterns included in the first electrode 210-1b or the second electrode 220-1b that has the same extension direction. In one or more embodiments, one portion of one third electrode 230-1b may overlap a portion of each of the first sensing patterns 2111-b included in one first electrode 210-1b, and another portion of the one third electrode 230-1b may overlap a portion of each of the first sensing patterns 211-1b included in another first electrode 210-1b. That is, one third electrode 230-1b may overlap portions of two first electrodes 210-1b. One first electrode 210-1b may overlap portions of two third electrodes 230-1b.

One fourth electrode 240b may overlap each of the sensing patterns included in the first electrode 210-1b or the second electrode 220-1b that has the same extension direction. In one or more embodiments, one portion of one fourth electrode 240b may overlap a portion of each of the second sensing patterns 221-1b included in one second electrode 220-1b, and another portion of the one fourth electrode 240b may overlap a portion of each of the second sensing patterns 221-1b included in another second electrode 220-1b. That is, one fourth electrode 240b may overlap portions of two second electrodes 220. One second electrode 220-1b may overlap portions of two fourth electrodes 240b.

Two third electrodes 230-1b spaced apart from each other and two fourth electrodes 240b spaced apart from each other may be included in one sensing unit SU-1b where one first electrode 210-1b and one second electrode 220-1b cross each other. One third electrode 230-1b may be commonly included in sensing units SU-1b adjacent to each other in the direction perpendicular to the extension direction of the third electrode 230 (e.g., in the second direction DR2). One fourth electrode 240b may be commonly included in sensing units SU-1b adjacent to each other in the direction perpendicular to the extension direction of the fourth electrode 240 (e.g., in the first direction DR1).

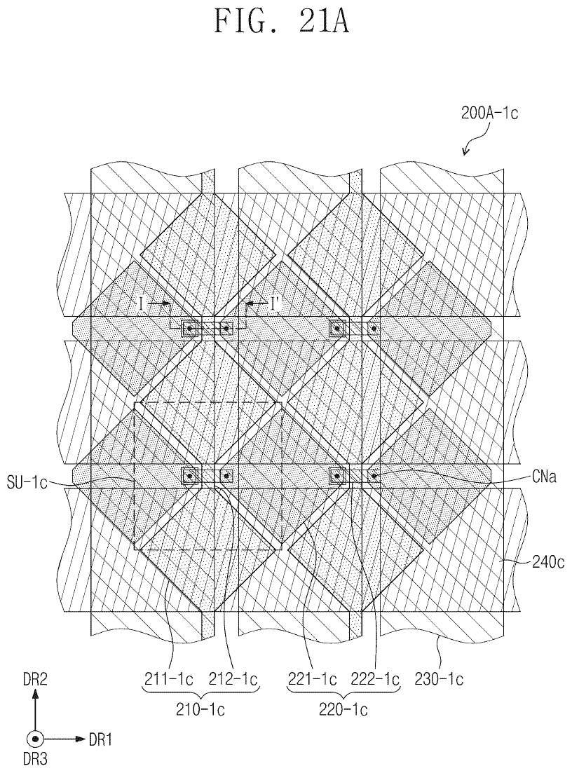

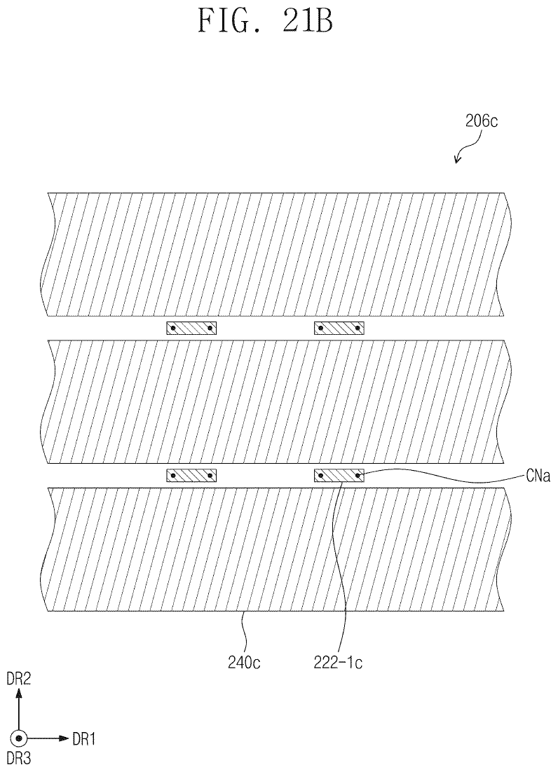

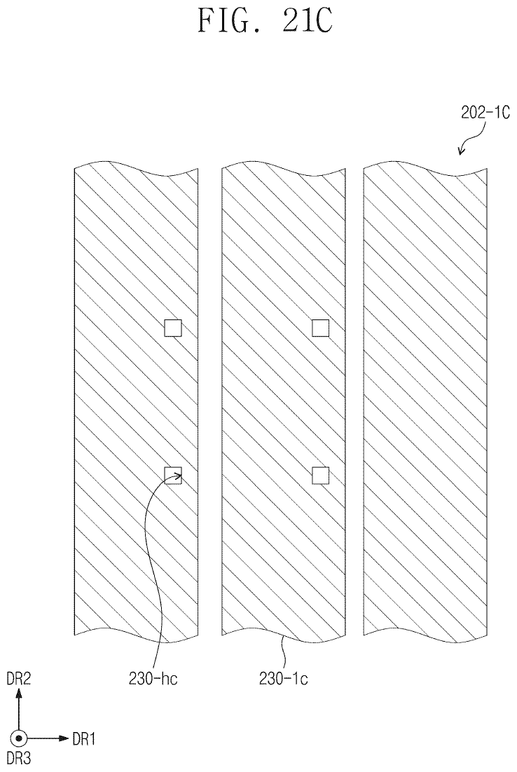

FIG. 21A is an enlarged plan view illustrating a portion of a sensing area 200A-1c according to one or more embodiments of the present disclosure. FIG. 21B is a plan view illustrating a lower conductive layer 206c of a portion of the sensing area 200A-1c according to one or more embodiments of the present disclosure. FIG. 21C is a plan view illustrating a first conductive layer 202-1c of a portion of the sensing area 200A-1c according to one or more embodiments of the present disclosure.

FIGS. 21A to 21C are enlarged views illustrating portions of two first electrodes 210-1c and two second electrodes 220-1c crossing each other, portions of three third electrodes 230-1c overlapping the two first electrodes 210-1c, and portions of three fourth electrodes 240c overlapping the two second electrodes 220-1c.

Referring to FIGS. 21A to 21C, each of the first electrodes 210-1c may include first sensing patterns 211-1c and first bridge patterns 212-1c. For one first electrode 210-1c, the first sensing patterns 211-1c and the first bridge patterns 212-1c may form a one-body shape (e.g., may be integrally formed). Each of the second electrodes 220-1c may include second sensing patterns 221-1c and second bridge patterns 222-1c. The second sensing patterns 221-1c and the second bridge patterns 222-1c may be electrically connected with each other through contact holes CNa.

The first electrodes 210-1c and the second sensing patterns 221-1c may be located on the same layer. For example, the first electrodes 210-1c and the second sensing patterns 221-1c may be included in the second conductive layer 204-1b (refer to FIG. 20D).

The second bridge patterns 222-1c may be located on a layer that is different from the layer on which the first electrodes 210-1c and the second sensing patterns 221-1c are located. The second bridge patterns 222-1c may be located on the same layer as the fourth electrodes 240c. For example, the second bridge patterns 222-1c and the fourth electrodes 240c may be included in the lower conductive layer 206c. The second sensing patterns 221-1c and the second bridge patterns 222-1c may be electrically connected with each other through the contact holes CNa defined in the intermediate insulating layer 203 (refer to FIG. 20D) and the lower insulating layer 207 (refer to FIG. 20D).

Each of the second bridge patterns 222-1c may extend in the first direction DR1. Each of the fourth electrodes 240c may extend in the same direction as the extension direction of the second bridge pattern 222-1c. The fourth electrode 240c may have a bar shape extending in the first direction DR1.

The third electrodes 230-1c may be located on a layer that is different from the layers on which the first electrodes 210-1c, the second electrodes 220-1c, and the fourth electrodes 240c are located. For example, the third electrodes 230-1c may be included in the first conductive layer 202-1c. Each of the third electrodes 230-1c may extend in the second direction DR2. The third electrode 230-1c may have a bar shape extending in the second direction DR2.

Holes 230-h may be defined in each of the third electrodes 230-1c. Two second sensing patterns 221-1c adjacent to each other in the first direction DR1 may be connected to a corresponding second bridge pattern 222-1c through the contact holes CNa. For one second bridge pattern 222-1c, one contact hole CNa to which one second sensing pattern 211-1c is connected may be located in the hole 230-hc defined in the third electrode 230-1c on the plane. The hole 230-hc may surround the corresponding contact hole CNa. The holes 230-hc defined in each of the third electrodes 230-1c may provide the spaces in which the contact holes CNa through which the second sensing patterns 221-1c and the second bridge patterns 222-1c are connected are defined. Meanwhile, for one second bridge pattern 222-1c, another contact hole CNa to which another second sensing pattern 211-1c is connected may be located outside the third electrode 230-1c.

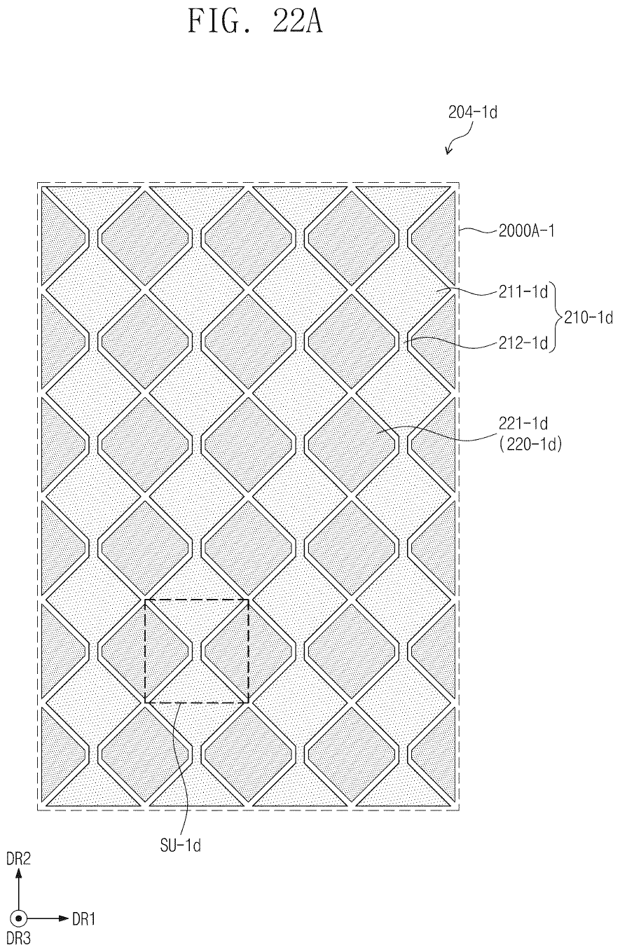

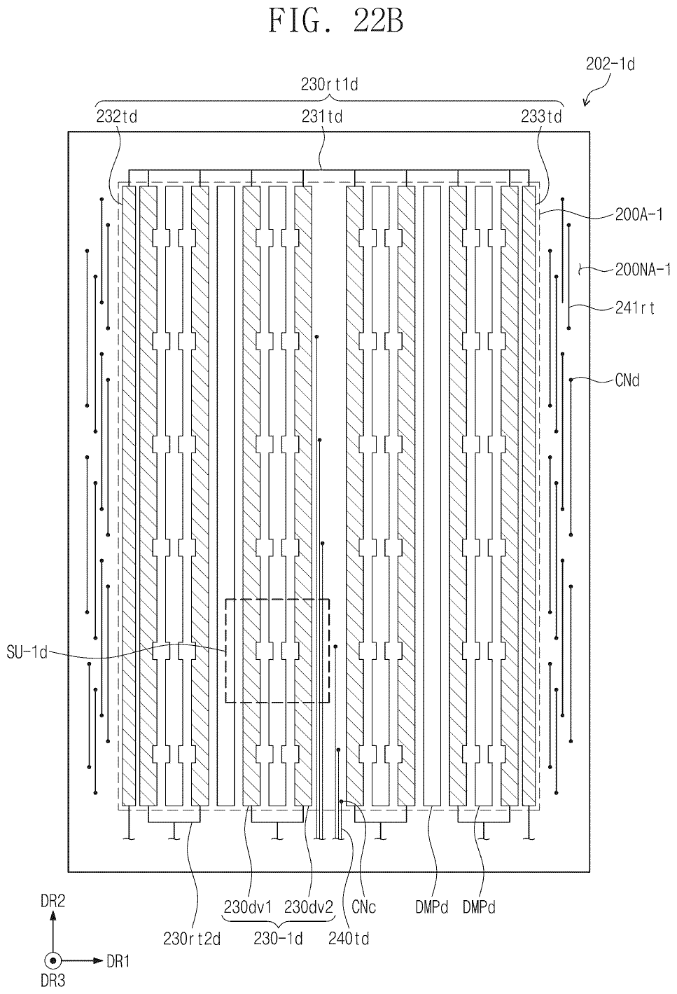

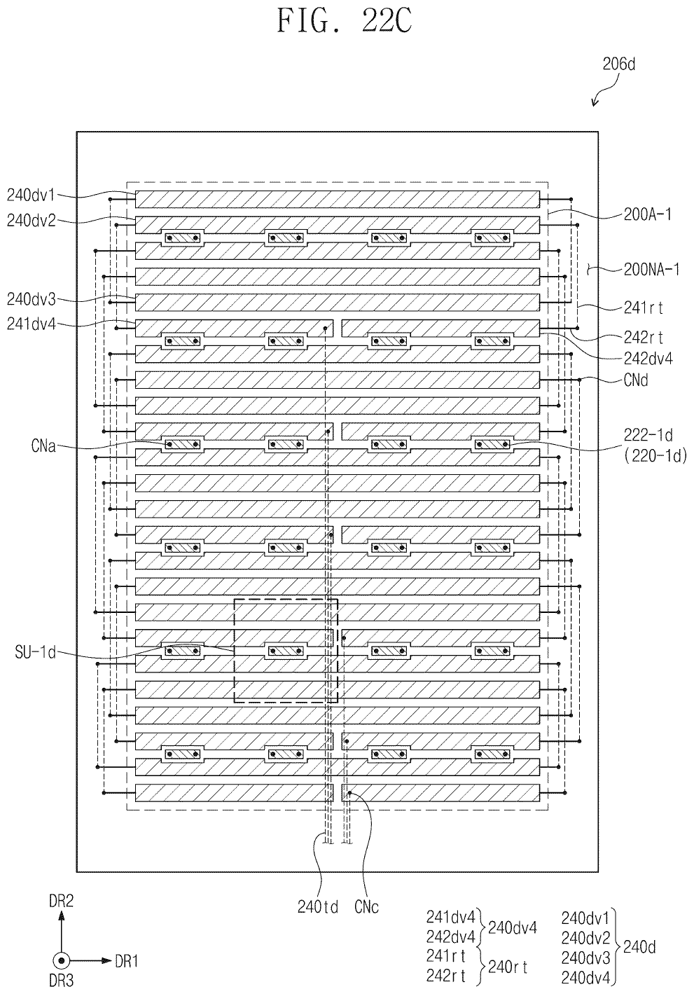

FIG. 22A is a plan view illustrating a second conductive layer 204-1d according to one or more embodiments of the present disclosure. FIG. 22B is a plan view illustrating a first conductive layer 202-1d according to one or more embodiments of the present disclosure. FIG. 22C is a plan view illustrating a lower conductive layer 206d according to one or more embodiments of the present disclosure.

FIGS. 22A to 22C illustrate four first electrodes 210-1d and six second electrodes 220-1d crossing each other, four third electrodes 230-1d overlapping the four first electrodes 210-1d, and six fourth electrodes 240d overlapping the six second electrodes 220-1d. In FIGS. 22A to 22C, 24 sensing units SU-1d where one first electrode 210-1d and one second electrode 220-1d cross each other are illustrated. However, the numbers of first to fourth electrodes 210-1d, 220-1d, 230-1d, and 240d are not limited thereto.

As illustrated in FIG. 22A, each of the first electrodes 210-1d may include first sensing patterns 211-1d and first bridge patterns 212-1d. For one first electrode 210-1d, the first sensing patterns 211-1d and the first bridge patterns 212-1d may form a one-body shape (e.g., may be integrally formed).

As illustrated in FIGS. 22A and 22C, each of the second electrodes 220-1d may include second sensing patterns 221-1d and second bridge patterns 222-1d. The second sensing patterns 221-1d and the second bridge patterns 222-1d may be electrically connected with each other through contact holes CNa. For one second electrode 220-1d, the second sensing patterns 221-1d and the second bridge patterns 222-1d may be located on different layers so as to be spaced apart from each other. For example, the first electrodes 210-1d and the second sensing patterns 221-1d may be included in the second conductive layer 204-1d, and the second bridge patterns 222-1d may be included in the lower conductive layer 206d.

As illustrated in FIG. 22B, the third electrodes 230-1d may be included in the first conductive layer 202-1d. Each of the third electrodes 230-1d may extend in the second direction DR2. The third electrodes 230-1d may be arranged in the first direction DR1 so as to be spaced apart from one another.

In one or more embodiments, each of the third electrodes 230-1d may include a first-first divided electrode 230dv1 and a first-second divided electrode 230dv2. The first-first divided electrode 230dv1 and the first-second divided electrode 230dv2 may extend in the second direction DR2, and may be spaced apart from each other in the first direction DR1. The first-first divided electrode 230dv1 and the first-second divided electrode 230dv2 may have line symmetry with respect to a line extending in the second direction DR2. A portion of each of the first-first divided electrode 230dv1 and the first-second divided electrode 230dv2 that form one third electrode 230-1d may overlap a portion of a corresponding first electrode 210-1d. That is, the third electrodes 230-1d may overlap the first electrodes 210-1d in a one-to-one correspondence.

In one or more embodiments, the first conductive layer 202-1d may further include dummy patterns DMPd. Each of the dummy patterns DMPd may be floated or electrically floated. The dummy pattern DMPd may be located between the first-first divided electrode 230dv1 and the first-second divided electrode 230dv2 adjacent to each other in the first direction DR1. The dummy pattern DMPd may extend in the second direction DR2.

Depressions (or, concave portions) may be defined in each of the first-first and first-second divided electrodes 230dv1 and 230dv2 and the dummy patterns DMPd located therebetween. The depressions defined in each of the first-first and first-second divided electrodes 230dv1 and 230dv2 and the dummy patterns DMPd located therebetween may be portions recessed in the extension direction of the second bridge patterns 222-1d (e.g., the first direction DR1). The depressions defined in the first-first divided electrode 230dv1 and the dummy pattern DMPd adjacent to each other, or the first-second divided electrode 230dv2 and the dummy pattern DMPd adjacent to each other, may face each other to provide the spaces defining the contact holes CNa through which the second sensing patterns 221-1d and the second bridge patterns 222-1d are connected.

As illustrated in FIG. 22C, the fourth electrodes 240d may be included in the lower conductive layer 206d. That is, the second bridge patterns 222-1d and the fourth electrodes 240d may be located on the same layer. Each of the fourth electrodes 240d may extend in the same direction as the extension direction of the second bridge patterns 222-1d. For example, each of the second bridge patterns 222-1d and the fourth electrodes 240d may extend in the first direction DR1.

Each of the fourth electrodes 240d may include a second-first divided electrode 240dv1, a second-second divided electrode 240dv2, a second-third divided electrode 240dv3, and a second-fourth divided electrode 240dv4. The second-first to second-third divided electrodes 240dv1, 240dv2, and 240dv3 may extend in the first direction DR1, and may be arranged in the second direction DR2 so as to be spaced apart from one another. The second-fourth divided electrode 240dv4 may include a first sub-electrode 241dv4 and a second sub-electrode 242dv4 that extend in the first direction DR1, and that are spaced apart from each other in the first direction DR1. That is, one of the second-first to second-fourth divided electrodes 240dv1, 240dv2, 240dv3, or 240dv4 may include two sub-electrodes.

In one or more embodiments, for one fourth electrode 240d, the second-first and second-second divided electrodes 240dv1 and 240dv2 may be located adjacent to each other, and the second-third and second-fourth divided electrodes 240dv3 and 240dv4 may be located adjacent to each other. For another fourth electrode 240d, the second-first and second-second divided electrodes 240dv1 and 240dv2 may be located adjacent to each other, and the second-third and second-fourth divided electrodes 240dv3 and 240dv4 may be located adjacent to each other. Between the second-first and second-second divided electrodes 240dv1 and 240dv2 and the second-third and second-fourth divided electrodes 240dv3 and 240dv4 in one fourth electrode 240, the second-first and second-second divided electrodes 240dv1 and 240dv2, or the second-third and second-fourth divided electrodes 240dv3 and 240dv4 in another fourth electrode 240d, may be located.

Depressions (or, concave portions) may be defined in some of the second-first to second-fourth divided electrodes 240dv1, 240dv2, 240dv3, and 240dv4. Each of the depressions may be a portion recessed in the direction perpendicular to the extension direction of the second bridge patterns 222-1d (e.g., in the second direction DR2). Depressions defined in divided electrodes adjacent to each other in the second direction DR2 among the second-first to second-fourth divided electrodes 240dv1, 240dv2, 240dv3, and 240dv4 may face each other to provide the spaces in which the second bridge patterns 222-1d are located.

The sensor layer 200-1 (refer to FIG. 17) may further include a third trace line 230rt1d and fourth trace lines 230rt2d. The third trace line 230rt1d and the fourth trace lines 230rt2d may be electrically connected with the third electrodes 230-1d. The third trace line 230rt1d and the fourth trace lines 230rt2d may be located on the same layer as the third electrodes 230-1d. For example, the third trace line 230rt1d and the fourth trace lines 230rt2d may be included in the first conductive layer 202-1d. The third trace line 230rt1d may include a first line portion 231td, a second line portion 232td, and a third line portion 233td. FIG. 22B illustrates an example that the widths of the second line portion 232td and the third line portion 233td in the first direction DR1 are relatively thick. In addition, FIG. 22B illustrates an example that the first line portion 231td overlaps the peripheral area 200NA-1, and that the second line portion 232td and the third line portion 233td overlap the sensing area 200A-1. However, embodiments are not limited thereto. For example, as in the embodiments described with reference to FIGS. 7 and 17, the second line portion 232td and the third line portion 233td may overlap the peripheral area 200NA-1.

The sensor layer 200-1 (refer to FIG. 17) may further include fifth trace lines 240td. The fifth trace lines 240td may be referred to as first type trace lines. The fifth trace lines 240td may be electrically connected with the fourth electrodes 240d. The fifth trace lines 240td may be located on a layer that is different from the layer on which the fourth electrodes 240d are located. For example, the fifth trace lines 240td may be included in the first conductive layer 202-1d, and may be located on the same layer as the third electrodes 230-1d.

The fifth trace lines 240td may at least partially overlap the sensing area 200A-1. The fifth trace lines 240td that are located on the layer that is different from the layer on which the fourth electrodes 240d are located may overlap the fourth electrodes 240d, or may cross the fourth electrodes 240d while being insulated from the fourth electrodes 240d. Each of the fifth trace lines 240td may be connected to a corresponding fourth electrode 240d through a contact hole CNc defined in the lower insulating layer 207 (refer to FIG. 20D). Each of the fifth trace lines 240td may be connected to an end portion of the first sub-electrode 241dv4 or the second sub-electrode 242dv4 in a corresponding second-fourth divided electrode 240dv4. Because the fifth trace lines 240td at least partially overlap the sensing area 200A-1, the area occupied by the peripheral area 200NA-1 on the front surface of the electronic device 1000 (refer to FIG. 1A) may be reduced, and a narrow bezel may be implemented.

The sensor layer 200-1 (refer to FIG. 17) may further include sixth trace lines 240rt located in the peripheral area 200NA-1. The sixth trace lines 240rt may be referred to as second type trace lines. The sixth trace lines 240rt may connect the second-first to second-fourth divided electrodes 240dv1, 240dv2, 240dv3, and 240dv4 in one fourth electrode 240d. The sixth trace lines 240rt may connect first ends or second ends of two divided electrodes among the second-first to second-fourth divided electrodes 240dv1, 240dv2, 240dv3, and 240dv4. For example, in one fourth electrode 240d, the sixth trace lines 240rt may sequentially connect the first sub-electrode 241dv4 of the second-fourth divided electrode 240dv4, the second-first divided electrode 240dv1, the second-third divided electrode 240dv3, the second-second divided electrode 240dv2, and the second sub-electrode 242dv4 of the second-fourth divided electrode 240dv4.

The sixth trace lines 240rt may include first layer lines 241rt and second layer lines 242rt. Each of the first layer lines 241rt may extend in the second direction DR2, and each of the second layer lines 242rt may extend in the first direction DR1. The second layer lines 242rt may be directly connected to first ends or second ends of the second-first to second-fourth divided electrodes 240dv1, 240dv2, 240dv3, and 240dv4. The first layer lines 241rt may connect the second layer lines 242rt to connect the second-first to second-fourth divided electrodes 240dv1, 240dv2, 240dv3, and 240dv4 in one fourth electrode 240d. The first layer lines 241rt and the second layer lines 242rt may be located on different layers. The second layer lines 242rt may be included in the lower conductive layer 206d, and may be located on the same layer as the fourth electrodes 240d. The first layer lines 241rt may be included in the first conductive layer 202-1d, and may be located on the same layer as the third electrodes 230-1d.

Although the first trace lines 210t (refer to FIG. 17) connected to the first electrodes 210-1d and the second trace lines 220t (refer to FIG. 17) connected to the second electrodes 220-1d are omitted in FIGS. 22A to 22C, the sensor layer 200-1 (refer to FIG. 17) may further include the first trace lines 210t (refer to FIG. 17) and the second trace lines 220t (refer to FIG. 17) located in the peripheral area 200NA-1. For example, the first and second trace lines 210t and 220t (refer to FIG. 17) may be included in the second conductive layer 204-1d.

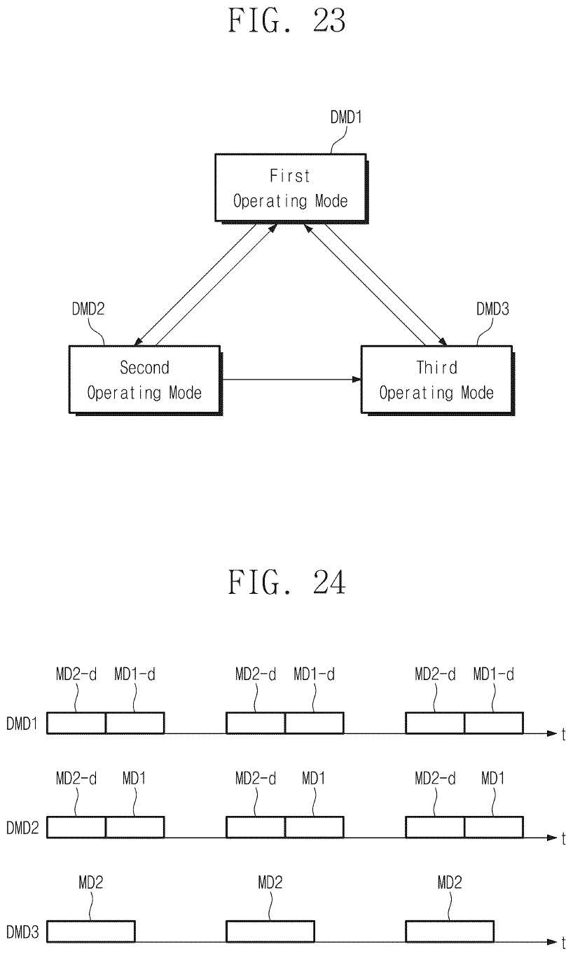

FIG. 23 is a view illustrating an operation of the sensor driver 200C (refer to FIG. 5) according to one or more embodiments of the present disclosure.

Referring to FIGS. 5 and 23, the sensor driver 200C may be selectively driven in one of a first operation mode DMD1, a second operation mode DMD2, or a third operation mode DMD3.

The first operation mode DMD1 may be referred to as a touch-and-pen-standby mode, the second operation mode DMD2 may be referred to as a touch-activation-and-pen-standby mode, and the third operation mode DMD3 may be referred to as a pen activation mode. The first operation mode DMD1 may be a mode in which the sensor driver 200C waits for the first input 2000 and the second input 3000. The second operation mode DMD2 may be a mode in which the sensor driver 200C senses the first input 2000 and waits for the second input 3000. The third operation mode DMD3 may be a mode in which the sensor driver 200C senses the second input 3000.

In one or more embodiments of the present disclosure, the sensor driver 200C may first be driven in the first operation mode DMD1. When the first input 2000 is sensed in the first operation mode DMD1, the sensor driver 200C may be switched (or, changed) to the second operation mode DMD2. Alternatively, when the second input 3000 is sensed in the first operation mode DMD1, the sensor driver 200C may be switched (or, changed) to the third operation mode DMD3.

In one or more embodiments of the present disclosure, when the second input 3000 is sensed in the second operation mode DMD2, the sensor driver 200C may be switched to the third operation mode DMD3. When the first input 2000 is released (or, not sensed) in the second operation mode DMD2, the sensor driver 200C may be switched to the first operation mode DMD1. When the second input 3000 is released (or, not sensed) in the third operation mode DMD3, the sensor driver 200C may be switched to the first operation mode DMD1.

FIG. 24 is a view illustrating an operation of the sensor driver 200C (refer to FIG. 5) according to one or more embodiments of the present disclosure.

Referring to FIGS. 5, 23, and 24, operations in the first to third operation modes DMD1, DMD2, and DMD3 are illustrated in order of time (t).

In the first operation mode DMD1, the sensor driver 200C may be repeatedly driven in a second mode MD2-d and a first mode MD1-d. During the second mode MD2-d, the sensor layer 200 may be scan-driven to detect the second input 3000. During the first mode MD1-d, the sensor layer 200 may be scan-driven to detect the first input 2000. Although FIG. 24 illustrates an example that the sensor driver 200C operates in the first mode MD1-d continuously after the second mode MD2-d, the sequence is not limited thereto.

In the second operation mode DMD2, the sensor driver 200C may be repeatedly driven in a second mode MD2-d and a first mode MD1. During the second mode MD2-d, the sensor layer 200 may be scan-driven to detect the second input 3000. During the first mode MD1, the sensor layer 200 may be scan-driven to detect the coordinates by the first input 2000.

In the third operation mode DMD3, the sensor driver 200C may be driven in a second mode MD2. During the second mode MD2, the sensor layer 200 may be scan-driven to detect the coordinates by the second input 3000. In the third operation mode DMD3, the sensor driver 200C may not operate in the first mode MD1-D or MD1 until the second input 3000 is released (or, not sensed).

Referring also to FIG. 17, in the first mode MD1-d and in the first mode MD1, all of the third electrodes 230-1 and the fourth electrodes 240 may be grounded, or may receive a constant voltage. Alternatively, in the first mode MD1-d and the first mode MD1, the third electrodes 230-1 and the fourth electrodes 240 may all be floated. In another case, in the first mode MD1-d and the first mode MD1, a signal in phase with a transmission signal provided to the first electrodes 210-1 may be applied to the third electrodes 230-1 and the fourth electrodes 240. In this case, touch noise may be reduced or prevented from being introduced through the third electrodes 230-1 and the fourth electrodes 240.

In the second mode MD2-d and the second mode MD2, first ends of the third electrodes 230-1 and the fourth electrodes 240 may all be floated. In addition, in the second mode MD2-d and the second mode MD2, second ends of the third electrodes 230-1 and the fourth electrodes 240 may all be grounded or floated. Accordingly, compensation of a sensing signal may be improved or maximized by the coupling between the first electrodes 210-1 and the third electrodes 230-1 and the coupling between the second electrodes 220-1 and the fourth electrodes 240.

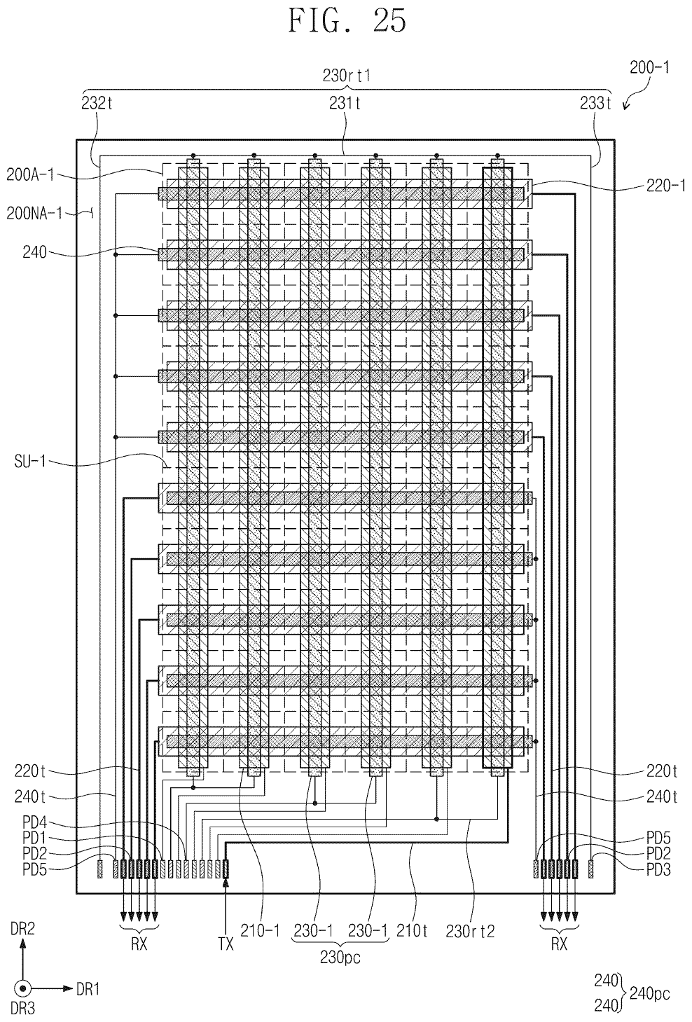

FIG. 25 is a view for explaining the first mode according to one or more embodiments of the present disclosure.

Referring to FIGS. 5, 24, and 25, the first mode MD1-d of the first operation mode DMD1 and the first mode MD1 of the second operation mode DMD2 may include a mutual capacitance detection mode. FIG. 25 is a view for explaining the mutual capacitance detection mode in the first mode MD1-d of the first operation mode DMD1 and in the first mode MD1 of the second operation mode DMD2.

In the mutual capacitance detection mode, the sensor driver 200C may sequentially provide a transmission signal TX to the first electrodes 210-1, and may detect the coordinates for the first input 2000 using a reception signal RX detected through the second electrodes 220-1. For example, the sensor driver 200C may sense a change in the mutual capacitance between the first electrodes 210-1 and the second electrodes 220-1, and may calculate input coordinates.

FIG. 25 illustrates an example that the transmission signal TX is provided to one first electrode 210-1 and that the reception signal RX is output from the second electrodes 220-1. In FIG. 25, to clarify the expression of the signal, one first electrode 210-1 to which the transmission signal TX is provided is darkly displayed (e.g., displayed in bold). The sensor driver 200C may sense a change in the capacitance between the first electrode 210-1 and each of the second electrodes 220-1, and may detect the input coordinates for the first input 2000.

In one or more embodiments of the present disclosure, at least one of the first mode MD1-d of the first operation mode DMD1 or the first mode MD1 of the second operation mode DMD2 may further include a self-capacitance detection mode. In the self-capacitance detection mode, the sensor driver 200C may calculate input coordinates by outputting driving signals to the first electrodes 210-1 and the second electrodes 220-1, and by sensing a change in the capacitance of each of the first electrodes 210-1 and the second electrodes 220-1.

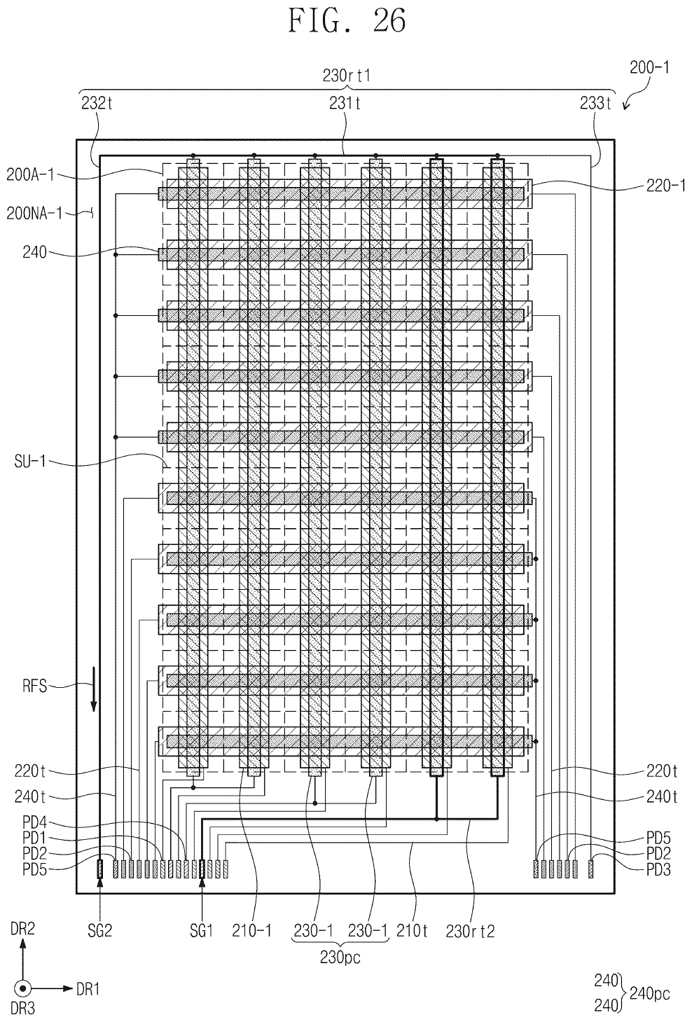

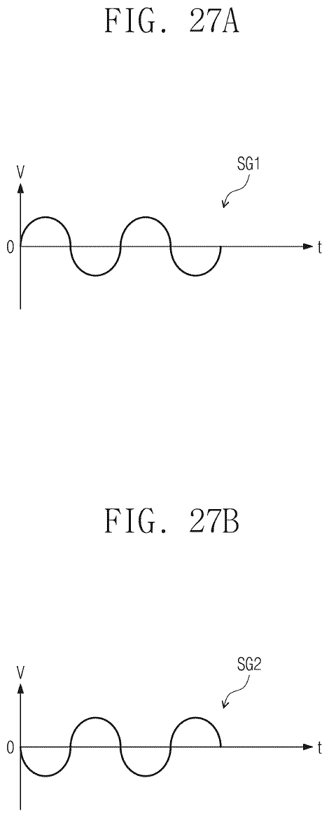

FIG. 26 is a view for explaining the second mode, for example, the charging driving mode according to one or more embodiments of the present disclosure. FIG. 27A is a graph depicting the waveform of a first signal according to one or more embodiments of the present disclosure. FIG. 27B is a graph depicting the waveform of a second signal according to one or more embodiments of the present disclosure.

Referring to FIGS. 26, 27A, and 27B, the second mode MD2 may include the charging driving mode. The charging driving mode may include a searching-charging driving mode and a tracking-charging driving mode.

The searching-charging driving mode may be a driving mode before the position of the pen PN is sensed. Accordingly, the first signal SG1 or the second signal SG2 may be provided to all channels included in the sensor layer 200-1. That is, in the searching-charging driving mode, the entire area of the sensor layer 200-1 may be scanned. When the pen PN is sensed in the searching-charging driving mode, the sensor layer 200-1 may be driven in the tracking-charging driving mode. For example, in the tracking-charging driving mode, the sensor driver 200C may sequentially output the first signal SG1 and the second signal SG2 to an area overlapping the point where the pen PN is sensed, rather than the entire sensor layer 200-1.

In the charging driving mode, the sensor driver 200C may apply the first signal SG1 to one pad among the third pads PD3 and the fourth pads PD4 and may apply the second signal SG2 to another pad. The second signal SG2 may be an inverse signal of the first signal SG1. For example, the first signal SG1 may be a sinusoidal signal.

Because the first signal SG1 and the second signal SG2 are applied to at least two pads, a current RFS may have a current path to flow through one pad to another pad. In addition, because the first signal SG1 and the second signal SG2 are sinusoidal signals having an inverse phase relationship, the direction of the current RFS may be periodically varied. In one or more embodiments of the present disclosure, the first signal SG1 and the second signal SG2 may be square-wave signals having an inverse phase relationship.

When the first signal SG1 and the second signal SG2 have an inverse phase relationship, noise caused in the display layer 100 (refer to FIG. 4) by the first signal SG1 may be reduced or cancelled out by noise caused by the second signal SG2. Thus, a flicker phenomenon may not occur in the display layer 100, and the display quality of the display layer 100 may be improved.

In one or more embodiments of the present disclosure, the first signal SG1 may be a sinusoidal signal. However, without being limited thereto, the first signal SG1 may be a square-wave signal. The second signal SG2 may have a certain constant voltage. For example, the second signal SG2 may be a ground voltage. That is, a pad to which the second signal SG2 is applied may be regarded as being grounded. Even in this case, the current RFS may flow from one pad to another pad. In addition, even though the other pad is grounded, the direction of the current RFS may be periodically varied because the first signal SG1 is a sinusoidal signal or a square-wave signal.

Referring to FIG. 26, the second signal SG2 is provided to one third pad PD3 connected with one third trace line 230rt1, and the first signal SG1 is provided to one fourth pad PD4 connected with the third electrode 230-1. The current RFS may flow along a current path defined by the fourth pad PD4, the fourth trace line 230rt2 connected to the fourth pad PD4, the third electrode 230-1, a portion of the third trace line 230rt1 connected to the third pad PD3, and the third pad PD3. The current path may have a coil shape. Accordingly, in the charging driving mode of the second mode, the resonance circuit of the pen PN may be charged by the current path.

According to the present disclosure, a current path having a loop coil pattern may be implemented by components included in the sensor layer 200-1. Accordingly, the electronic device 1000 (refer to FIG. 1A) may charge the pen PN using the sensor layer 200-1. Thus, a component having a coil for charging the pen PN does not need to be separately added, so that an increase in the thickness and weight of the electronic device 1000 and a decrease in the flexibility of the electronic device 1000 may not occur.

In the charging driving mode, the first electrodes 210-1, the second electrodes 220-1, and the fourth electrodes 240 may be grounded or electrically floated, or may receive a constant voltage. For example, the first electrodes 210-1, the second electrodes 220-1, and the fourth electrodes 240 may be floated. In this case, the current RFS may not flow to the first electrodes 210-1, the second electrodes 220-1, and the fourth electrodes 240.

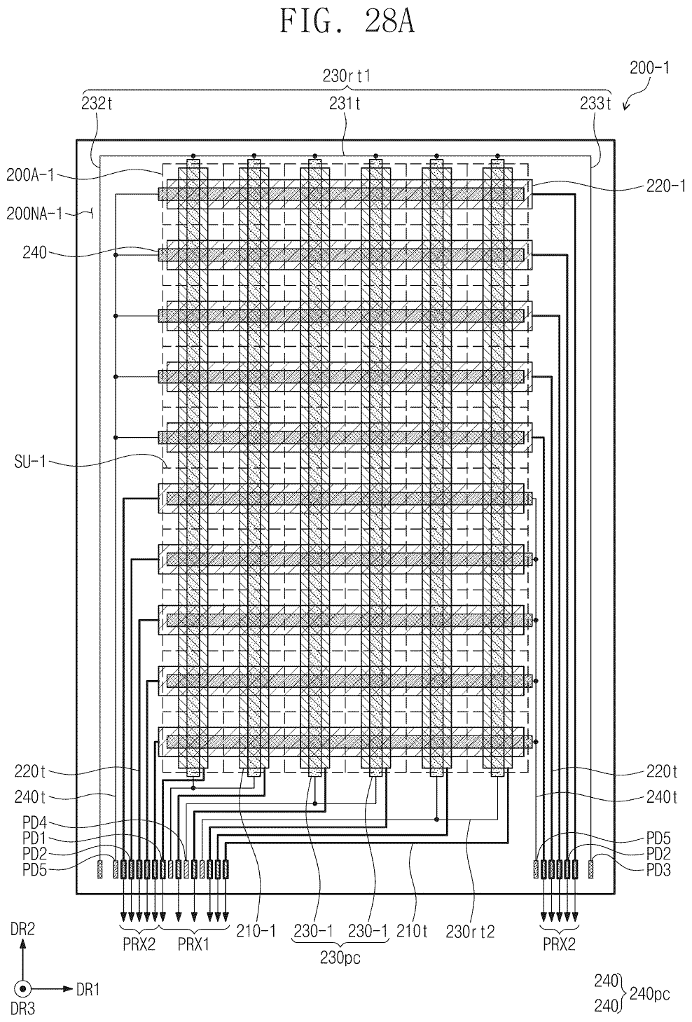

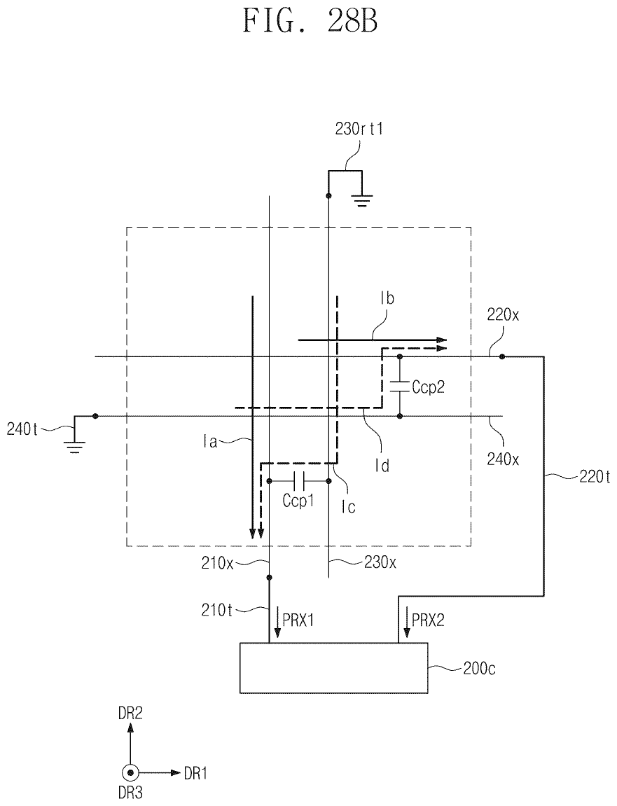

FIG. 28A is a view for explaining the second mode according to one or more embodiments of the present disclosure. FIG. 28B is a view for explaining the second mode based on one sensing unit according to one or more embodiments of the present disclosure.

Referring to FIGS. 5, 28A, and 28B, the second mode may include a charging driving mode and a pen-sensing driving mode. FIGS. 28A and 28B are views for explaining the pen-sensing driving mode. In FIG. 28B, one sensing unit SU-1 through which first to fourth induced currents Ia, Ib, Ic, and Id generated by the pen PN flow is illustrated.

In one or more embodiments of the present disclosure, the routing directions of one electrode and another electrode of the sensor layer 200-1 that overlap each other may be different from each other. For example, the routing direction of a first electrode 210x and the routing direction of a third electrode 230x may be different from each other. In addition, the routing direction of a second electrode 220x and the routing direction of a fourth electrode 240x may be different from each other. For example, in FIG. 28B, the first electrode 210x and the first trace line 210t may be connected on the lower side of the sensing unit SU-1, and the third electrode 230x and the third trace line 230rt1 may be connected on the upper side of the sensing unit SU-1. The second electrode 220x and the second trace line 220t may be connected on the right side of the sensing unit SU-1, and the fourth electrode 240x and the fifth trace line 240t may be connected on the left side of the sensing unit SU-1.

The RLC resonance circuit of the pen PN may emit a magnetic field having a resonant frequency while discharging charged charges. Due to the magnetic field provided by the pen PN, the first induced current Ia may be generated in the first electrode 210x, and the second induced current Ib may be generated in the second electrode 220x. In addition, the third induced current Ic may be generated in the third electrode 230x, and the fourth induced current Id may be generated in the fourth electrode 240x.

A first coupling capacitor Ccp1 may be formed between the third electrode 230x and the first electrode 210x, and a second coupling capacitor Ccp2 may be formed between the fourth electrode 240x and the second electrode 220x. The third induced current Ic may be transferred to the first electrode 210x through the first coupling capacitor Ccp1, and the fourth induced current Id may be transferred to the second electrode 220x through the second coupling capacitor Ccp2.

The sensor driver 200c may receive a first reception signal PRX1 based on the first induced current Ia and the third induced current Ic from the first electrode 210x, and may receive a second reception signal PRX2 based on the second induced current Ib and the fourth induced current Id from the second electrode 220x. The sensor driver 200C may detect the input coordinates of the pen PN based on the first reception signal PRX1 and the second reception signal PRX2.

The sensor driver 200C may receive the first reception signal PRX1 from the first electrode 210x, and may receive the second reception signal PRX2 from the second electrode 220x. In this case, first ends of the third electrode 230x and the fourth electrode 240x may all be floated. Accordingly, compensation of a sensing signal may be improved or maximized by the coupling between the first electrode 210x and the third electrode 230x and by the coupling between the second electrode 220x and the fourth electrode 240x.

In addition, second ends of the third electrode 230x and the fourth electrode 240x may be grounded or floated. Accordingly, the third induced current Ic and the fourth induced current Id may be sufficiently transferred to the first electrode 210x and to the second electrode 220x by the coupling between the first electrode 210x and the third electrode 230x and by the coupling between the second electrode 220x and the fourth electrode 240x.

As described above, not only the touch input, but also the pen input, may be sensed using the sensor layer. Accordingly, a separate component (e.g., a digitizer) for sensing the pen does not need to be added to the electronic device, and thus, an increase in the thickness and weight of the electronic device and a decrease in the flexibility of the electronic device otherwise occurring due to the addition of the digitizer may not occur.

In addition, the sensor layer may include the first and second electrodes that sense the touch input and the pen input, and the third electrode (or, the third and fourth electrodes) that causes or recognizes electromagnetic induction. In this case, there may be provided the sensor layer in which the first and second electrodes have a structure capable of improving capacitance sensing sensitivity, and in which the third electrode (or, the third and fourth electrodes) has a structure capable of reducing or minimizing resistance. Thus, the electronic device with improved pen sensitivity and touch sensitivity may be provided.

While the present disclosure has been described with reference to embodiments thereof, it will be apparent to those of ordinary skill in the art that various changes and modifications may be made thereto without departing from the spirit and scope of the present disclosure as set forth in the following claims, with functional equivalents thereof to be included therein.

What is claimed is:

1. An electronic device comprising:
a sensor layer; and
a sensor driver configured to drive the sensor layer, and configured to selectively operate in a first mode to sense a touch input or in a second mode to sense a pen input,
wherein the sensor layer comprises:
first electrodes arranged in a first direction, and comprising first sensing patterns spaced apart in a second direction crossing the first direction, and a first bridge pattern between the first sensing patterns;
second electrodes arranged in the second direction, and comprising second sensing patterns spaced apart in the first direction, and a second bridge pattern between the second sensing patterns; and
pen-sensing electrodes at a same layer as, and extending in an extension direction of, one of the first bridge pattern or the second bridge pattern.

2. The electronic device of claim 1, wherein the pen-sensing electrodes are at a same layer as the second bridge pattern, and wherein the pen-sensing electrodes and the second bridge pattern extend in the first direction.

3. The electronic device of claim 2, wherein the pen-sensing electrodes have a bar shape extending in the first direction.

4. The electronic device of claim 2, wherein an outer edge of the pen-sensing electrodes faces an outer edge of the second bridge pattern adjacent thereto.

5. The electronic device of claim 2, wherein the pen-sensing electrodes alternate with the second bridge patterns in the second direction.

6. The electronic device of claim 2, wherein a portion of one of the pen-sensing electrodes overlaps a portion of two of the second electrodes.

7. The electronic device of claim 2, wherein a portion of two of the pen-sensing electrodes is in a sensing unit where one of the first electrodes and one of the second electrodes cross.

8. The electronic device of claim 2, wherein the first electrodes and the second sensing patterns are at a different layer from the second bridge pattern,
wherein the first sensing patterns and the first bridge pattern are integral in one of the first electrodes, and
wherein the second sensing patterns and the second bridge pattern are connected through contact holes in one of the second electrodes.

9. The electronic device of claim 1, wherein the pen-sensing electrodes are at a same layer as the second bridge pattern, and
wherein the pen-sensing electrodes and the second bridge pattern extend in the second direction.

10. The electronic device of claim 9, wherein the second sensing patterns comprise a first protrusion on one side in the first direction, and a second protrusion on an opposite side in the first direction, the first and second protrusions extending in the first direction, and
wherein the second bridge pattern is connected to the second protrusion of one of the second sensing patterns and to the first protrusion of another of the second sensing patterns.

11. The electronic device of claim 10, wherein the first bridge pattern comprises a first line portion configured to extend from one side of one of the first sensing patterns toward another one of the first sensing patterns adjacent thereto, a second line portion configured to extend from one side of the other of the first sensing patterns toward the one of the first sensing patterns, and a third line portion connecting the first and second line portions and extending in the first direction,
wherein the second protrusion of the one of the second sensing patterns is between the other of the first sensing patterns and the third line portion, and
wherein the first protrusion of the other of the second sensing patterns is between the one of the first sensing patterns and the third line portion.

12. The electronic device of claim 1, wherein the pen-sensing electrodes are at a same layer as the first bridge pattern, and wherein the pen-sensing electrodes and the first bridge pattern extend in the second direction.

13. The electronic device of claim 12, wherein the pen-sensing electrodes have a bar shape extending in the first direction, and
wherein an outer edge of the pen-sensing electrodes faces an outer edge of the second bridge pattern adjacent thereto.

14. The electronic device of claim 12, wherein the pen-sensing electrodes define a hole surrounding the first bridge pattern in plan view, and
wherein the pen-sensing electrodes overlap the first electrodes in a one-to-one correspondence.

15. The electronic device of claim 12, wherein the first sensing patterns and the second electrodes are at a different layer from the first bridge pattern,
wherein the first sensing patterns and the first bridge pattern in one of the first electrodes are connected through contact holes, and
wherein the second sensing patterns and the second bridge pattern are integral in one of the second electrodes.

16. The electronic device of claim 1, further comprising floated dummy patterns between adjacent ones of the pen-sensing electrodes.

17. The electronic device of claim 1, wherein the pen-sensing electrodes define depressions recessed in a direction perpendicular to an extension direction of the second bridge pattern, and
wherein at least portions of the second bridge pattern are in the depressions of the pen-sensing electrodes adjacent to the second bridge pattern.

18. The electronic device of claim 1, wherein the pen-sensing electrodes comprise:
first pen-sensing electrodes arranged in the first direction, and extending in the second direction; and
second pen-sensing electrodes arranged in the second direction, and extending in the first direction.

19. The electronic device of claim 18, wherein the first pen-sensing electrodes comprise third sensing patterns spaced apart in the second direction, and a third bridge pattern between the third sensing patterns,
wherein the second pen-sensing electrodes comprise fourth sensing patterns spaced apart in the first direction, and a fourth bridge pattern between the fourth sensing patterns,
wherein the second bridge pattern, the third sensing patterns, and the second pen-sensing electrodes are at a same layer,
wherein the first electrodes, the second sensing patterns, and the third bridge pattern are at a same layer, and
wherein the second pen-sensing electrodes and the second bridge pattern extend in the first direction.

20. The electronic device of claim 19, wherein the second bridge pattern and the fourth bridge pattern are adjacent, are spaced apart in the second direction, and extend in parallel.

21. The electronic device of claim 19, wherein the second pen-sensing electrodes define a hole surrounding the second bridge pattern in plan view.

22. The electronic device of claim 19, wherein the first pen-sensing electrodes and the second pen-sensing electrodes are at different respective layers,
wherein the second pen-sensing electrodes are at a same layer as the second bridge pattern,
wherein the second pen-sensing electrodes and the second bridge pattern extend in the second direction,
wherein the first pen-sensing electrodes extend in the first direction, and
wherein the second pen-sensing electrodes have a bar shape extending in the second direction.

23. The electronic device of claim 22, wherein the sensor layer comprises a lower conductive layer, a first conductive layer above the lower conductive layer, and a second conductive layer above the first conductive layer,
wherein the first pen-sensing electrodes are in the lower conductive layer,
wherein the second pen-sensing electrodes and the second bridge pattern are in the first conductive layer,
wherein the first electrodes and the second sensing patterns are in the second conductive layer, and
wherein the first pen-sensing electrodes have a bar shape extending in the first direction.

24. The electronic device of claim 22, wherein the sensor layer comprises a lower conductive layer, a first conductive layer above the lower conductive layer, and a second conductive layer above the first conductive layer,
wherein the second pen-sensing electrodes and the first bridge pattern are in the lower conductive layer,
wherein the first pen-sensing electrodes are in the first conductive layer,
wherein the first electrodes and the second sensing patterns are in the second conductive layer, and
wherein the first pen-sensing electrodes define a hole surrounding, in plan view, a contact hole through which one of the second sensing patterns and the second bridge pattern are connected.

25. The electronic device of claim 18, wherein the first pen-sensing electrodes comprise first divided electrodes spaced apart in the first direction, and
wherein the sensor layer further comprises dummy patterns between the first divided electrodes, arranged in the first direction, and extending in the second direction.

26. The electronic device of claim 18, wherein the sensor layer further comprises first type trace lines respectively connected to the second pen-sensing electrodes at a same layer as the first pen-sensing electrodes and extending to cross at least portions of the second pen-sensing electrodes in plan view while being insulated therefrom.

27. The electronic device of claim 26, wherein the second pen-sensing electrodes comprise second divided electrodes arranged in the second direction, and comprising a first sub-electrode and a second sub-electrode spaced apart in the first direction, and
wherein the first type trace lines are connected to the first sub-electrode or the second sub-electrode of a corresponding one of the second pen-sensing electrode.

28. The electronic device of claim 18, wherein the second pen-sensing electrodes comprise second divided electrodes arranged in the second direction,
wherein the sensor layer further comprises second type trace lines to connect first ends or second ends of the second divided electrodes in one second pen-sensing electrode, and
wherein the second type trace lines comprise a first layer line at a same layer as the first pen-sensing electrodes, and a second layer line at a same layer as the second pen-sensing electrodes.

29. The electronic device of claim 1, wherein the first electrodes, the second electrodes, and the pen-sensing electrodes have a mesh structure defining openings.

30. The electronic device of claim 1, wherein, in the first mode, the first electrodes and the second electrodes are configured to sense capacitance, and the pen-sensing electrodes are grounded, and
wherein the second mode comprises a pen-sensing driving mode in which the sensor driver is configured to receive reception signals based on induced currents flowing through the first electrodes, the second electrodes, and the pen-sensing electrodes.

31. The electronic device of claim 30, wherein the second mode further comprises a charging driving mode in which a current path defined by at least the pen-sensing electrodes is formed, and the first electrodes and the second electrodes are floated.

32. An electronic device comprising:
a sensor layer; and
a sensor driver configured to drive the sensor layer,
wherein the sensor layer comprises:
first electrodes arranged in a first direction, and comprising first sensing patterns spaced apart in a second direction crossing the first direction, and a first bridge pattern between the first sensing patterns;
second electrodes arranged in the second direction, and comprising second sensing patterns spaced apart in the first direction, and a second bridge pattern between the second sensing patterns; and
auxiliary electrodes at a same layer as, and extending in an extension direction of, one of the first bridge pattern or the second bridge pattern such that outer edges face each other.

33. The electronic device of claim 32, wherein the first sensing patterns and the second sensing patterns are above the auxiliary electrodes.

34. The electronic device of claim 32, wherein the sensor driver is configured to selectively operate in a first mode to sense a touch input, or in a second mode to sense a pen input,
wherein, in the first mode, the first electrodes and the second electrodes are configured to sense capacitance, and the auxiliary electrodes are grounded, and
wherein, in the second mode, the sensor driver is configured to receive reception signals based on induced currents flowing through the first electrodes, the second electrodes, and the auxiliary electrodes.
